(19) United States
(12) Patent Application Publication
(10) Pub. No.: US 2026/0090294 A1
(43) Pub. Date: Mar. 26, 2026

(54) DOPED SILICON OR BORON LAYER FORMATION

(71) Applicant: Lam Research Corporation, Fremont, CA (US)

(72) Inventors: Nuoya Yang, Frisco, TX (US); Yuxi Wang, Beaverton, OR (US); Bo Gong, Sherwood, OR (US); Andrew John McKerrow, Lake Oswego, OR (US)

(21) Appl. No.: 19/109,493

(22) PCT Filed: Sep. 1, 2023
(86) PCT No.: PCT/US2023/031873

§ 371 Date: Mar. 6, 2025

Related U.S. Application Data
(60) Provisional application No. 63/374,715, filed on Sep. 6, 2022.
(60) Provisional application No. 63/377,112, filed on Sep. 26, 2022.

(51) Int. Cl. H10P 14/60; C23C 16/24; C23C 16/50; H01J 37/32

(52) U.S. Cl. CPC H10P 14/6532; C23C 16/24; C23C 16/50; H01J 37/32357; H10P 14/6334; H10P 14/6544; H01J 2237/3365

(57) ABSTRACT

An amorphous silicon layer or amorphous boron layer can be deposited on a substrate using one or more silicon or boron-containing precursors, respectively. Radical species are provided from a plasma source or from a controlled reaction chamber atmosphere to convert the amorphous silicon layer to a doped silicon layer with composition tunability. An initiation layer is deposited on one or more semiconductor device structures having a dielectric layer over an electrically conductive layer. The initiation layer may be conformally deposited by a CVD-based process and may comprises amorphous silicon, doped silicon, amorphous boron, or doped boron.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

Many semiconductor device fabrication processes involve forming silicon-based dielectric films. Silicon-based dielectric films may include films including two elements such as silicon oxide, silicon carbide, or silicon nitride; or three element films such as silicon oxynitride, silicon oxycarbide, or silicon carbonitride; or four element films such as silicon oxycarbonitride. Depositing a high-quality film with controlled composition can be particularly challenging. Challenges can also include the formation of non-conformal film on high aspect ratio structures.

Semiconductor device fabrication process also include boron-containing films due to their low dielectric constant, adhesion to other films, electromigration performance with copper, barrier properties, etch selectivity, low current leakage, and high thermal stability, among other properties. Boron-containing films may include boron nitride, boron carbide, or boron carbonitride.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Provided are methods of forming a doped silicon layer on a semiconductor substrate. The methods may include forming an amorphous silicon layer on a semiconductor substrate in a reaction chamber, and exposing the amorphous silicon layer to a gas plasma flow to convert the amorphous silicon layer to the doped silicon layer.

In some embodiments, the gas plasma flow includes radicals of nitrogen, oxygen, hydrogen, or carbon.

In some embodiments, the gas plasma flow includes a remote plasma flow.

In some embodiments, the method further includes generating a remote plasma of a source gas in a remote plasma source. The method further includes introducing the remote plasma as the remote plasma flow through a showerhead into the reaction chamber. The source gas includes nitrogen-containing reactants, hydrogen-containing reactants, hydrocarbons, oxygen or oxide reactants, or combinations thereof. The source gas includes nitrogen (N₂), ammonia (NH₃), diazene (N₂H₂), hydrazine (N₂H₄), acetylene (C₂H₂), ethylene (C₂H₄), propene (C₃H₆), hydrogen (H₂), methane (CH₄), oxygen (O₂), water (H₂O), carbon monoxide (CO), carbon dioxide (CO₂), nitrous oxide (N₂O), nitrogen dioxide (NO₂), or combinations thereof. A composition of the source gas in the remote plasma source is controlled to tune a composition of the doped silicon layer.

In some embodiments, forming the amorphous silicon layer includes flowing a silicon-containing precursor to adsorb on surfaces of the semiconductor substrate, and thermally decomposing the silicon-containing precursor to form the amorphous silicon layer. The silicon-containing precursor has a sticking coefficient of 0.05 or less. The silicon-containing precursor includes silane, disilane, or trisilane.

In some embodiments, the amorphous silicon layer has a conformality of at least 90%.

In some embodiments, the doped silicon layer includes silicon oxide, silicon nitride, silicon carbide, silicon oxycarbide, silicon oxynitride, silicon carbonitride, or silicon oxycarbonitride.

In some embodiments, the doped silicon layer includes a silicon-nitrogen-containing layer, wherein the gas plasma flow includes one or more of the following gas species: nitrogen (N₂), ammonia (NH₃), diazene (N₂H₂), or hydrazine (N₂H₄).

In some embodiments, the doped silicon layer includes a silicon-carbon-containing layer, wherein the gas plasma flow includes one or more of the following gas species: acetylene (C₂H₂), ethylene (C₂H₄), or propene (C₃H₆).

In some embodiments, the gas plasma flow includes one or more of the following gas species: hydrogen (H₂), or methane (CH₄).

In some embodiments, the doped silicon layer includes a silicon-oxygen-containing layer, wherein the gas flow includes one or more of the following gas species: oxygen (O₂), water (H₂O), carbon monoxide (CO), carbon dioxide (CO₂), nitrous oxide (N₂O), or nitrogen dioxide (NO₂).

In some embodiments, the gas plasma flow is produced from an inductively coupled plasma or a capacitively coupled plasma.

Another aspect of the disclosure relates to a method of forming a doped silicon layer. The method includes forming a conformal silicon layer on a substrate in a reaction chamber. The method further includes generating a remote plasma of a source gas in a remote plasma source. The source gas includes one or more of the following: nitrogen, oxygene, hydrogen, or carbon. The method further includes exposing the conformal silicon layer to the remote plasma to convert the conformal silicon layer to the doped silicon layer.

In some embodiments, the conformal silicon layer includes an amorphous silicon layer.

In some embodiments, the doped silicon layer includes silicon oxide, silicon nitride, silicon carbide, silicon oxycarbide, silicon oxynitride, silicon carbonitride, or silicon oxycarbonitride.

In some embodiments, the doped silicon layer includes a silicon-nitrogen-containing layer. The source gas includes one or more of the following gas species: nitrogen (N₂), ammonia (NH₃), diazene (N₂H₂), or hydrazine (N₂H₄).

In some embodiments, the doped silicon layer includes a silicon-carbon-containing layer. The source gas includes one or more of the following gas species: acetylene (C₂H₂), ethylene (C₂H₄), or propene (C₃H₆).

In some embodiments, the source gas includes one or more of the following gas species: hydrogen (H₂), or methane (CH₄).

In some embodiments, the doped silicon layer includes a silicon-oxygen-containing layer, wherein the gas plasma flow includes one or more of the following gas species: oxygen (O₂), water (H₂O) vapor, carbon monoxide (CO), carbon dioxide (CO₂), nitrous oxide (N₂O), or nitrogen dioxide (NO₂).

Another aspect of the disclosure relates to a method of forming a crystallized boron-containing layer. The method includes forming an amorphous boron layer on a substrate in a reaction chamber, and heating the substrate to a temperature equal to or greater than about 200° C. The method further includes exposing the amorphous boron layer to one or more gas species to convert the amorphous boron layer to the crystallized boron-containing layer.

In some embodiments, the crystallized boron-containing layer is selected from the group consisting of boron carbide, boron nitride, boron oxide, boron oxynitride, boron oxycarbide, boron carbonitride, or boron oxy carbonitride.

In some embodiments, the one or more gas species include one or more of the following gas species: nitrogen (N₂), ammonia (NH₃), diazene (N₂H₂), or hydrazine (N₂H₄), acetylene (C₂H₂), ethylene (C₂H₄), propene (C₃H₆), hydrogen (H₂), methane (CH₄), oxygen (O₂), water (H₂O), carbon monoxide (CO), carbon dioxide (CO₂), nitrous oxide (N₂O), or nitrogen dioxide (NO₂).

In some embodiments, forming the amorphous boron-containing layer includes flowing a boron-containing precursor to adsorb on the surfaces of the substrate, and thermally decomposing the boron-containing precursor to form the amorphous boron layer. The boron-containing precursor includes: borane, diborane, triborane, tetraborane, pentaborane, hexaborane, decaborane, or combinations thereof.

Another aspect of the disclosure relates to the methods of forming a doped boron layer. The method includes forming an amorphous boron layer on a semiconductor substrate in a reaction chamber. The method further includes exposing the amorphous boron layer to a gas plasma flow to convert the amorphous boron layer to the doped boron layer.

In some embodiments, the gas plasma flow includes radicals of one or more of the following: nitrogen, oxygen, hydrogen, or carbon.

In some embodiments, the gas plasma flow includes a remote plasma flow.

In some embodiments, the doped boron layer includes boron carbide, boron nitride, boron oxide, boron oxynitride, boron oxycarbide, boron carbonitride, or boron oxycarbonitride.

Another aspect of the disclosure relates to a method of forming a crystallized silicon-containing layer. The method includes forming an amorphous silicon layer on a substrate in a reaction chamber, and heating the substrate to a temperature equal to or greater than about 200° C. The method further includes exposing the amorphous silicon layer to one or more gas species to convert the amorphous silicon layer to the crystallized silicon-containing layer.

Another aspect of the disclosure relates to a method of depositing a spacer layer on one or more semiconductor device structures. The method includes providing, in a process chamber, a semiconductor substrate having one or more semiconductor device structures, wherein each of the one or more semiconductor device structures includes a dielectric capping layer over an electrically conductive layer. The method also includes conformally depositing an amorphous silicon initiation layer on the dielectric capping layer and the electrically conductive layer of the one or more semiconductor device structures, and depositing the spacer layer on the amorphous silicon initiation layer.

In some embodiments, conformally depositing the amorphous silicon initiation layer and depositing the spacer layer occur in the process chamber.

In some embodiments, depositing the spacer layer on the amorphous silicon initiation layer includes: exposing the semiconductor substrate to a precursor in the process chamber; generating, from a hydrogen source gas, radicals of hydrogen in a remote plasma source located upstream of the process chamber; and introducing the radicals of hydrogen into the process chamber and towards the semiconductor substrate to react with the precursor to form the spacer layer.

In some embodiments, conformally depositing the amorphous silicon initiation layer includes depositing the amorphous silicon initiation layer by thermal chemical vapor deposition (CVD).

In some embodiments, depositing the amorphous silicon initiation layer by thermal CVD includes: exposing the one or more semiconductor device structures to a silane-based precursor; and applying thermal energy to thermally decompose the silane-based precursor to deposit the amorphous silicon initiation layer.

The method further includes: exposing the amorphous silicon initiation layer to plasma, prior to depositing the spacer layer, to form a doped silicon layer including silicon carbide, silicon oxycarbide, silicon carbonitride, or silicon oxycarbonitride.

In some embodiments, the dielectric capping layer includes silicon nitride and the electrically conductive layer includes tungsten or molybdenum.

In some embodiments, the spacer layer is deposited substantially uniformly over the dielectric capping layer and the electrically conductive layer.

In some embodiments, the spacer layer includes silicon oxycarbide.

In some embodiments, each of the one or more semiconductor device structures further includes a semiconductor layer including polysilicon, wherein the electrically conductive layer is over the semiconductor layer.

In some embodiments, the amorphous silicon initiation layer has a thickness between about 2 Å and about 30 Å.

In some embodiments, conformally depositing the amorphous silicon initiation layer includes depositing the amorphous silicon initiation layer at a temperature between about 400° C. and about 650° C.

In some embodiments, the electrically conductive layer in each of the one or more semiconductor device structures includes a bitline in a memory array.

Another aspect of the disclosure relates to a method of depositing a spacer layer on one or more semiconductor device structures. The method includes: providing, in a process chamber, a semiconductor substrate having one or more semiconductor device structures, wherein each of the one or more semiconductor device structures includes a dielectric capping layer over an electrically conductive layer; conformally depositing a silicon-based initiation layer on the dielectric capping layer and the electrically conductive layer of the one or more semiconductor device structures, wherein the silicon-based initiation layer includes silicon carbide, silicon oxycarbide, silicon carbonitride, or silicon oxycarbonitride; and depositing a spacer layer on the silicon-based initiation layer.

In some embodiments, conformally depositing the silicon-based initiation layer includes: exposing the one or more semiconductor device structures to a silane-based precursor in the process chamber; applying thermal energy to thermally decompose the silane-based precursor to form an amorphous silicon layer in the process chamber; and exposing the amorphous silicon layer to plasma in the process chamber to form the silicon-based initiation layer on the electrically conductive layer and dielectric capping layer.

In some embodiments, applying thermal energy to thermally decompose the silane-based precursor to form the amorphous silicon layer includes exposing the semiconductor substrate to an elevated temperature between about 400° C. and about 650° C.

In some embodiments, depositing the spacer layer includes: exposing the one or more semiconductor device structures to a silicon-containing precursor in the process chamber; generating, from a hydrogen source gas, radicals of hydrogen in a remote plasma source located upstream of the process chamber; and introducing the radicals of hydrogen into the process chamber and towards the semiconductor substrate to react with the silicon-containing precursor to form the spacer layer.

In some embodiments, the dielectric capping layer includes silicon nitride, the electrically conductive layer includes tungsten or molybdenum, and the spacer layer includes silicon oxycarbide.

In some embodiments, the silicon-based initiation layer is deposited substantially uniformly over the dielectric capping layer and the electrically conductive layer.

Another aspect of the disclosure relates to an apparatus. The apparatus includes: a process chamber; a pedestal configured to support a semiconductor substrate in the process chamber, wherein the semiconductor substrate includes one or more semiconductor device structures, wherein each of the one or more semiconductor device structures includes a dielectric capping layer over an electrically conductive layer; a gas supply line configured to deliver precursor gases to the process chamber; a remote plasma source positioned upstream of the process chamber and configured to generate remote plasma; and a controller configured with instructions to conformally deposit a silicon-based initiation layer on the dielectric capping layer and the electrically conductive layer in the process chamber and to deposit a spacer layer on the silicon-based initiation layer in the process chamber.

In some embodiments, the silicon-based initiation layer includes amorphous silicon.

In some embodiments, the controller is further configured with instructions to expose the amorphous silicon to the remote plasma to form the silicon-based initiation layer on which the spacer layer is formed, wherein the remote plasma includes plasma-activated species of one or more dopant gases including one or more of nitrogen, oxygen, hydrogen, or carbon.

In some embodiments, the dielectric capping layer includes silicon nitride, the electrically conductive layer includes tungsten or molybdenum, and the spacer layer includes silicon oxycarbide.

These and other features of the disclosed embodiments will be described in detail below with reference to the associated drawings.

### BRIEF DESCRIPTION OF DRAWINGS

FIG. 1 presents a flow diagram of operations for forming a doped silicon layer according to some embodiments.

FIG. 2 presents a flow diagram of operations for forming a doped silicon layer according to some embodiments.

FIG. 3A-3B show graphs of Fourier-Transform infrared spectroscopy (FTIR) absorbance spectra for detecting bond type in a silicon nitride layer and a silicon carbide layer, respectively, according to some embodiments.

FIG. 4A shows a cross-sectional schematic illustration of an example semiconductor device structure having a spacer layer uniformly deposited on a dielectric capping layer and an electrically conductive layer of the semiconductor device structure.

FIG. 4B shows a cross-sectional schematic illustration of an example semiconductor device structure having a spacer layer non-uniformly deposited on a dielectric capping layer and an electrically conductive layer of the semiconductor device structure due to the effects of nucleation delay.

FIG. 5 illustrates a flow chart of an example method of forming a spacer layer on one or more semiconductor device structures according to some embodiments.

FIG. 6 illustrates a flow chart of an example method of forming a spacer layer on one or more semiconductor device structures according to some other embodiments.

FIGS. 7A-7C show cross-sectional schematic illustrations of an example semiconductor substrate undergoing formation of spacers on a plurality of semiconductor device structures according to some embodiments.

FIG. 8 illustrates a schematic diagram of a semiconductor processing apparatus for performing deposition according to some embodiments.

FIG. 9 illustrates a schematic diagram of an example plasma processing apparatus with a remote plasma source according to some embodiments.

FIG. 10 illustrates a schematic diagram of an example plasma processing apparatus with a remote plasma source according to some embodiments.

### DETAILED DESCRIPTION

In the following description, numerous specific details are set forth to provide a thorough understanding of the presented embodiments. The disclosed embodiments may be practiced without some or all these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

In the present disclosure, the terms “semiconductor wafer,” “wafer,” “substrate,” and “semiconductor substrate” are used interchangeably. One of ordinary skill in the art would understand that the term “substrate” can refer to a silicon wafer during any of many stages of integrated circuit fabrication. A wafer or substrate used in the semiconductor device industry typically has a diameter of 200 mm, or 300 mm, or 450 mm. The following detailed description assumes the present disclosure is implemented on a wafer. However, the present disclosure is not so limited. The work piece may be of various shapes, sizes, and materials. In addition to semiconductor wafers, other work pieces that may take advantage of the present disclosure include various articles such as printed circuit boards and the like.

In the present disclosure, the terms “depositing,” and “forming” are used interchangeably. Also, the terms “layer” and “film” are used interchangeably. One of ordinary skill in the art would understand that “forming” a layer in any of many stages of integrated circuit fabrication can refer to “depositing” a thin layer by one of various thin film forming methods such as physical vapor deposition (PVD), chemical vapor deposition (CVD), low pressure chemical vapor deposition (LPCVD), plasma enhanced chemical vapor deposition (PECVD), hot-wire chemical vapor deposition (hot-wire CVD), atomic layer deposition (ALD), or plasma enhanced atomic layer deposition (PEALD) due to the decreased feature sizes in a semiconductor device.

As used herein in the present disclosure, the term “doped silicon” refers to any silicon-containing material, crystallized or amorphous, doped with one, two, three, or more than three elements. Such elements include but are not limited to oxygen, nitrogen, carbon, and mixtures thereof. Examples of “doped silicon” may comprise silicon oxide, silicon nitride, silicon carbide, silicon oxycarbide, silicon oxynitride, silicon carbonitride, and silicon oxycarbonitride. In such instances, “doped silicon” may be synonymous with doped silicon oxide, doped silicon nitride, doped silicon carbide, doped silicon oxycarbide, doped oxynitride, doped silicon carbonitride, and doped silicon oxycarbonitride. The term “doped boron” refers to any boron-containing material, crystallized or amorphous, doped with one, two, three, or more than three elements. Such elements include but are not limited to oxygen, nitrogen, carbon, and mixtures thereof. Examples of “doped boron” may comprise boron carbide, boron nitride, boron oxide, boron oxynitride, boron oxycarbide, boron carbonitride, and boron oxycarbonitride. In such instances, “doped boron” may be synonymous with doped boron carbide, doped boron nitride, doped boron oxide, doped boron oxynitride, doped boron oxycarbide, doped boron carbonitride, and doped oxycarbonitride.

Manufacture of semiconductor devices typically involves forming one or more silicon-based thin films on a semiconductor substrate in an integrated fabrication process. Silicon-based thin films may include silicon oxide, silicon nitride, or doped or undoped silicon carbide. Technology nodes are continually shrinking in the integrated circuit manufacturing industry. With each technology node, device geometries also shrink, and pitch becomes smaller. High aspect ratio gaps in such technology nodes may need to be filled with insulating material, such as insulating material with a low dielectric constant (low-k). Semiconductor integration operations may involve filling high aspect ratio gaps with low-k dielectric materials. This is the case for shallow trench isolation, inter-metal dielectric layers, passivation layers, and the like. In another example, as device features shrink laterally, unwanted conductive coupling may occur as conductive materials get closer and closer, which can lead to parasitic capacitance, delay in signal propagation, and signal crosstalk due to capacitive effects. Low-k materials as the interlayer dielectric (ILD) of conductive interconnects may reduce parasitic capacitance, signal delay, and signal crosstalk. Some applications, including fin field effect transistor (finFET) structures and dynamic random-access memory (DRAM) bit structures, require low-k materials as sidewall spacer materials.

Silicon nitride is often used as an insulating material in many integrated circuit applications because of its step coverage, thermal stability, etch-ability and etch resistance, and high breakdown voltages.

Silicon oxide has a lower dielectric constant, which is about 4.0, and can provide a significant reduction in capacitance as an interlayer dielectric of conductive interconnects.

Silicon carbide materials, including doped and undoped silicon carbide materials, may serve as insulating materials in integrated circuit applications that provide not only a low dielectric constant, but also step coverage, thermal stability, wet etch resistance, dry etch selectivity to oxide/nitride, and high breakdown voltages. For example, incorporation of oxygen atoms and/or nitrogen atoms may tune the properties of silicon carbide materials. In some embodiments, an oxygen doped silicon carbide film can serve as an insulating material in integrated circuit applications that provides a low dielectric constant, wet etch resistance to survive device integration operations, and dry etch selectivity to oxide/nitride.

In some semiconductor fabrication processes, silicon-based thin films may be deposited using PVD, CVD, LPCVD, PECVD, hot-wire CVD, ALD, or PEALD, or any other suitable deposition method. As used herein, the term silicon carbide includes undoped or doped silicon carbides, such as oxygen doped silicon carbide, also known as silicon oxycarbide, nitrogen doped silicon carbide, also known as silicon carbonitride, and nitrogen and oxygen doped silicon carbide, also known as silicon oxycarbonitride. For many, doped silicon carbides have at most about 50 atomic percent of dopant atoms, whether those atoms are oxygen, nitrogen, or atoms of another element. The doping level provides desired film properties.

In some embodiments, a doped silicon layer may be formed as vertical structures adjacent to metal or semiconductor structures. For example, a doped silicon layer may include silicon oxide, silicon nitride, silicon carbide, silicon oxycarbide, silicon oxynitride, silicon carbonitride, or silicon oxycarbonitride. Deposition of a doped silicon layer provides excellent step coverage along sidewalls of the structures to create the vertical structures. PEALD may be suitable for forming a conformal layer. PEALD process may include two sequential steps: (a) self-limiting precursor adsorption on substrates and (b) plasma conversion to target film composition, which may be separated by purge operations. Due to its self-limited absorption and reaction mechanism, PEALD may achieve excellent conformal deposition in high aspect ratio (HAR) structures including HAR gapfill applications in both logic and memory integration, e.g., S/DTI (shallow/deep trench isolation) and memory hole in 3D-NAND. According to various embodiments, the methods may be used to fill challenging structures including extreme HAR (>200:1) structures, structures having re-entrant sidewall profile, and structures with smaller dimensions with low-k dielectric material. On the other hand, PEALD (or ALD) requires longer deposition time, which results in a reduced throughput compared to other deposition process such as PECVD (or CVD).

Forming high-quality doped silicon thin films may have certain challenges, such as providing films with excellent step coverage, low dielectric constants, and/or high breakdown voltages, etc. Other challenges may include composition control in a doped silicon layer after deposition. In some examples, a processing window for forming a doped silicon layer with stoichiometric composition may be relatively narrow. For example, unwanted oxidation in a doped or undoped silicon carbide layer may occur during the deposition process. Unwanted oxidation in a doped or undoped silicon carbide layer may increase oxygen content while decreasing the content for carbon or other non-oxygen elements in the undoped or doped silicon carbide layer. The deviation from stoichiometric composition may affect electrical properties in a semiconductor device incorporating the doped silicon layer.

One aspect of the present disclosure relates to a method of forming an amorphous silicon (a-Si) layer on a semiconductor substrate from one or more silicon-containing precursors by one of various processes such as PVD, CVD, LPCVD, PECVD, hot-wire CVD, ALD, or PEALD. The one or more silicon containing precursors may include at least one or more Si—Si bonds and/or Si—H bonds. For example, the silicon-containing precursor may include silane. The a-Si layer may have excellent step coverage to form a conformal layer. Subsequently, the a-Si layer may be exposed to a gas plasma flow generated from a plasma source. The plasma source may be a remote plasma source. The gas species in the gas plasma flow may include radicals of one or more of carbon, oxygen, hydrogen, or nitrogen. One or more gas species in the gas plasma flow may be adsorbed to treat the a-Si layer. It is to be understood that “treating” an a-Si layer may be construed to convert an a-Si layer to a doped silicon layer by doping with one or more ions or radicals in a gas plasma flow. For example, one or more gas species in the gas plasma flow may be incorporated in the a-Si layer to convert the a-Si layer to the doped silicon layer such as stoichiometric or non-stoichiometric compositions of silicon oxide, silicon nitride, silicon carbide, silicon oxycarbide, silicon oxynitride, silicon carbonitride, or silicon oxy carbonitride.

In another aspect of the present disclosure, the a-Si layer may be exposed to one or more gas species at elevated temperatures to convert the a-Si layer to a crystallized silicon-containing layer. The one or more gas species may include one or more of the following: nitrogen (N₂), ammonia (NH₃), diazene (N₂H₂), or hydrazine (N₂H₄), acetylene (C₂H₂), ethylene (C₂H₄), propene (C₃H₆), hydrogen (H₂), methane (CH₄), oxygen (O₂), water (H₂O), carbon monoxide (CO), carbon dioxide (CO₂), nitrous oxide (N₂O), or nitrogen dioxide (NO₂). In some embodiments, the elevated temperature may be at least about 200° C., or between about 200° C. and about 650° C. One or more gas species may be adsorbed on the a-Si layer to treat the a-Si layer. It is to be understood that “treating” an a-Si layer may be construed to convert an a-Si layer to a crystallized silicon-containing layer by doping with one or more gas species at elevated temperatures. For example, one or more gas species may be incorporated in the a-Si layer to convert the a-Si layer to the crystallized silicon-containing layer such as stoichiometric or non-stoichiometric compositions of silicon oxide, silicon nitride, silicon carbide, silicon oxycarbide, silicon oxynitride, silicon carbonitride, or silicon oxycarbonitride.

In another aspect of the present disclosure, the aforementioned a-Si layer may be replaced with an amorphous boron (a-B) layer. The amorphous boron layer may be treated using a gas plasma flow of one or more gas species to convert the amorphous boron layer to a doped boron layer. The doped boron layer may include, for example, stoichiometric or non-stoichiometric compositions of boron carbide, boron nitride, boron oxide, boron oxynitride, boron oxycarbide, boron carbonitride, or boron oxycarbonitride. Alternatively, the amorphous boron layer may be treated using one or more gas species at elevated temperatures to convert the amorphous boron layer to a crystallized boron-containing layer. The crystallized boron-containing layer may include, for example, stoichiometric or non-stoichiometric compositions of boron carbide, boron nitride, boron oxide, boron oxynitride, boron oxycarbide, boron carbonitride, or boron oxycarbonitride.

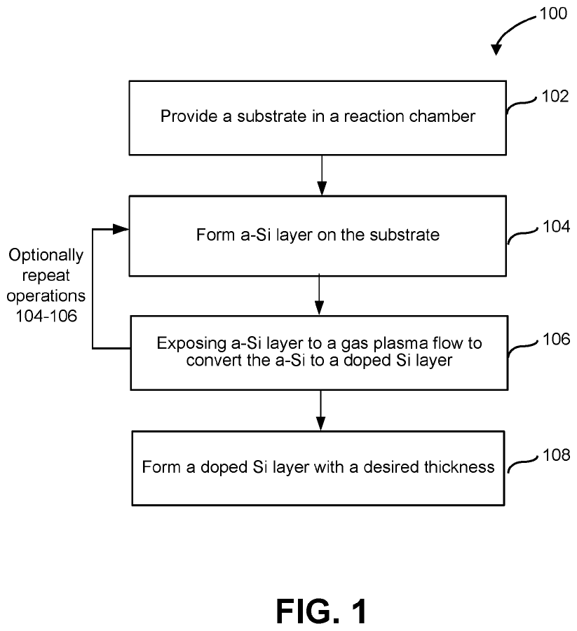

FIG. 1 presents a process flow diagram 100 for forming a doped silicon layer according to some embodiments. The process flow diagram 100 describes some embodiments in forming an a-Si layer on a substrate, and treating the a-Si layer by a plasma source. Treatment may convert the a-Si layer to a silicon-based layer having two or more elements. In some embodiments, the silicon-based layer may include at least a partially crystallized structure. In some embodiments, the silicon-based layer may include a fully crystallized structure. It is to be understood that formation of an a-Si layer and/or treatment of the a-Si layer by a plasma source may be conducted in an apparatus with a remote plasma source or in situ plasma source according to some embodiments.

In some embodiments, an amorphous boron (a-B) layer may be formed as an alternative to an a-Si layer, followed by treatment using a plasma source to convert the a-B layer to a doped boron layer with at least a partially crystallized structure. In some embodiments, the doped boron layer may include a fully crystallized structure.

In operation 102, a substrate is provided in a reaction chamber by a transfer system. In some embodiments, the substrate may be a semiconductor substrate. At least one or more regions of the substrate may include one or more features in which an a-Si layer is to be deposited. For some embodiments, the one or more features may include high aspect ratio (HAR) trenches or other recessed features in 3D-NAND or logic device. Prior to or after providing a substrate in a reaction chamber, the substrate may be optionally cleaned prior to depositing an a-Si layer on the substrate. For example, diluted hydrogen fluoride (HF) acid may be used to remove any contaminants or thin oxide layer on the substrate.

In operation 104, an a-Si layer may be formed on a substrate. Examples of techniques for forming the a-Si layer may include PVD, CVD, LPCVD, PECVD, hot-wire CVD, ALD, or PEALD. In some embodiments, the thickness of the a-Si layer can be controlled according to a predetermined deposition time to achieve a desired thickness. In some embodiments, the deposition time can be between about 5 seconds and about 500 seconds, or between about 10 seconds and about 200 seconds. In some embodiments, a desired thickness of the a-Si layer can be between about 0.1 nm and about 50 nm, between about 1 nm and about 30 nm, or between about 1 nm and about 20 nm. The deposition time can correspond to the desired thickness of the a-Si layer. The thickness may be controlled to enable sufficient penetration of radicals and/or ions in an a-Si layer from a subsequent plasma treatment.

For some embodiments, deposition of the a-Si layer can occur by flowing one or more silicon-containing precursors into the reaction chamber towards the substrate. The one or more silicon-containing precursors may adsorb on a surface of the substrate. The one or more silicon-containing precursors may thermally decompose to form the a-Si layer under certain CVD operating conditions (e.g., 400° C.-650° C., 0.1-30 Torr). Thermal decomposition breaks down the silicon-containing precursors into atoms and/or molecules for deposition on the surface of the substrate at elevated temperatures. Plasma-based deposition processes may lead to non-conformal deposition of a-Si, but thermal decomposition of silicon-containing precursors at sufficiently high temperatures may provide highly conformal deposition of a-Si. For some embodiments, forming an a-Si layer by PECVD process may necessitate controlling the deposition pressure ranging about 0.1-30 Torr, or about 0.5-20 Torr, or about 5-10 Torr. Substrate temperature during a-Si layer deposition may be controlled to be between about 200° C. and about 650° C., or between about 400° C. and about 650° C. The a-Si layer may be highly conformal. After deposition, a step coverage for the a-Si layer may be at least 85%, at least 90%, or at least 98%.

For some embodiments in CVD or PECVD, silicon-containing precursors may be continuously delivered to the substrate until a desired layer thickness is obtained. In other embodiments in ALD or PEALD, the a-Si layer may be formed by repeating: (1) pulsing one or more silicon containing precursors for a predetermined time, followed by (2) purging excess precursors. In some embodiments, the a-Si layer formed may not include long-range order. Instead, the a-Si layer may have a continuous random network of silicon atoms.

As described earlier, the a-Si layer according to some embodiments may provide a highly conformal a-Si layer. Without being limited by any theory, silicon-containing precursors having low sticking coefficients may be capable of producing highly conformal silicon layer. “Sticking coefficient” is a term used to describe the ratio of the number of adsorbate species (e.g., fragments or molecules) that adsorb/stick to a surface compared to the total number of species that impinge upon that surface during the same period of time. The symbol S_{c} is sometimes used to refer to the sticking coefficient. The value of S_{c} is between 0 (meaning that none of the species stick) and 1 (meaning that all of the impinging species stick). Various factors affect the sticking coefficient including the type of impinging species, surface temperature, surface coverage, structural details of the surface, and the kinetic energy of the impinging species. Certain species are inherently more “sticky” than others, making them more likely to adsorb onto a surface each time the species impinges on the surface. These more sticky species have greater sticking coefficients (all other factors being equal). In some cases, the sticking coefficient of the precursors (at the relevant deposition conditions) may be about 0.05 or less, for example about 0.001 or less.

In some embodiments, silicon-containing precursors may include at least one or more Si—Si bonds and/or at least one or more Si—H bonds. Silicon-containing precursors suitable for use in accordance with disclosed embodiments may include polysilanes (H₃Si—(SiH₂)ₙ—SiH₃), where n≥0. Examples of silanes are silane (SiH₄), disilane (Si₂H₆), trisilane (Si₃H₈), and organosilanes such as methylsilane, ethylsilane, isopropylsilane, t-butylsilane, dimethylsilane, diethylsilane, di-t-butylsilane, allylsilane, sec-butylsilane, thexylsilane, isoamylsilane, t-butyldisilane, di-t-butyldisilane, and the like.

In some embodiments, silicon-containing precursors may also include a halosilane. A halosilane includes at least one halogen group and may or may not include hydrogens and/or carbon groups. Examples of halosilanes are iodosilanes, bromosilanes, chlorosilanes, and fluorosilanes. Specific chlorosilanes are tetrachlorosilane, trichlorosilane, dichlorosilane, monochlorosilane, chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, t-butyldimethylchlorosilane, thexyldimethylchlorosilane, and the like.

In some embodiments, silicon-containing precursors may also include an aminosilane. An aminosilane includes at least one nitrogen atom bonded to a silicon atom, but may also contain hydrogens, oxygens, halogens, and carbons. Examples of aminosilanes are mono-, di-, tri- and tetra-aminosilane (H₃Si(NH₂), H₂Si(NH₂)₂, HSi(NH₂)₃ and Si(NH₂)₄, respectively), as well as substituted mono-, di-, tri- and tetra-aminosilanes, for example, t-butylaminosilane, methylaminosilane, tert-butylsilanamine, bis(tert-butylamino)silane (SiH₂(NHC(CH₃)₃)₂ (BTBAS), tert-butyl silylcarbamate, SiH(CH₃)—(N(CH₃)₂)₂, SiHCl—(N(CH₃)₂)₂, (Si(CH₃)₂NH)₃ and the like. A further example of an aminosilane is trisilylamine (N(SiH₃)). In some embodiments, an aminosilane that has two or more amine groups attached to the central Si atom may be used. These may result in less damage than aminosilanes having only a single amine group attached.

Further examples of silicon-containing precursors include trimethylsilane (3MS); ethylsilane; butasilanes; pentasilanes; octasilanes; heptasilane; hexasilane; cyclobutasilane; cycloheptasilane; cyclohexasilane; cyclooctasilane; cyclopentasilane; 1,4-dioxa-2,3,5,6-tetrasilacyclohexane; diethoxymethylsilane (DEMS); diethoxysilane (DES); dimethoxymethylsilane; dimethoxysilane (DMOS); methyl-diethoxysilane (MDES); methyl-dimethoxy silane (MDMS); octamethoxydodecasiloxane (OMODDS); tert-butoxydisilane; tetramethylcyclotetrasiloxane (TMCTS); tetraoxymethylcyclotetrasiloxane (TOMCTS); diethylsilane; triethoxysilane (TES); triethoxysiloxane (TRIES); and trimethoxysilane (TMS or TriMOS).

In some embodiments, an a-B layer may be deposited by any suitable process including PVD, CVD, LPCVD, PECVD, hot-wire CVD, ALD, or PEALD by providing one or more boron-containing precursors. Deposition of the a-B layer may proceed by flowing one or more boron-containing precursors into a reaction chamber towards a substrate. The one or more boron-containing precursors may adsorb on a surface of the substrate. The one or more boron-containing precursors may thermally decompose the a-B layer under certain CVD operating conditions.

The boron-containing precursor can be a borane precursor generally having a chemical formula BₓH_{y}. In some embodiments, the borane precursor is borane (BH₃). In some embodiments, the borane precursor is diborane (B₂H₆). In some embodiments, the borane precursor is a higher order borane such as triborane (B₃H₇), tetraborane (B₄H₁₀), pentaborane (B₅H₉), hexaborane (B₆H₁₀), or decaborane (B₁₀H₁₄).

Boranes may form stable complexes such as borane amine complexes. For example, a borane amine complex may include dimethylamineborane complex ((CH₃)₂NH:BH₃). The borane amine complex may generally have the chemical formula NR₃:BH₃, where R can be any combination of H or alkyl, allyl, alkenyl, alkynyl, alkylaryl, arylalkyl, phenyl, alkene, and alkyne ligands.

In some embodiments, the boron-containing precursor can be a borazine generally having a chemical formula BₓH_{y}N_{z}. For example, a borazine precursor can have the chemical formula B₃H₆N₃.

In addition to the gas species, an inert carrier gas or diluent gas can be flowed to the environment adjacent to the substrate. Examples of an inert carrier gas or diluent gas include but not limited to helium (He), neon (Ne), argon (Ar), krypton (Kr), xenon (Xe), and nitrogen (N₂). In some embodiments, a gas mixture of one or more source gases and one or more of the inert carrier gas or diluent gas may be provided in the remote plasma source.

In operation 106, the a-Si layer may be exposed to a gas plasma flow to convert the a-Si layer to a doped silicon layer. In some embodiments, the gas plasma flow includes radical species and/or ions that may be generated in the remote plasma source. The remote plasma source may be separated from the reaction chamber. A remote plasma flow including the gas plasma flow may be introduced into the reaction chamber through a showerhead toward the surface of the substrate to convert the a-Si layer to the doped silicon layer. The doped silicon layer includes silicon oxide, silicon nitride, silicon carbide silicon oxycarbide, silicon oxynitride, silicon carbonitride, or silicon oxycarbonitride. The a-Si layer may be exposed to the gas plasma flow generated in the plasma source. In some embodiments, the plasma source may be an in situ plasma source. In some embodiments, the plasma source may be a remote plasma source.

A source gas may be provided in the plasma source. The source gas may include gas species comprising nitrogen-containing reactants including nitrogen (N₂), ammonia (NH₃), diazene (N₂H₂), or hydrazine (N₂H₄); hydrogen-containing reactants including hydrogen (H₂) or methane (CH₄); hydrocarbons including acetylene (C₂H₂), ethylene (C₂H₄), or propene (C₃H₆); oxygen or oxide reactants including oxygen (O₂), water (H₂O), carbon monoxide (CO), carbon dioxide (CO₂), nitrous oxide (N₂O), or nitrogen dioxide (NO₂), or mixtures thereof. The gas species may be determined based on one or more doping elements required for forming the doped silicon layer. For example, nitrogen-containing reactants may be delivered to form a silicon nitride layer. In another example, carbon-containing reactants may be delivered to form a silicon carbide layer. For example, carbon-and nitrogen-containing reactants may be delivered to the a-Si layer to form a silicon carbonitride. In another example, silicon oxycarbide layer may be formed by exposing the a-Si layer to oxygen- and carbon-containing reactants. In yet another example, oxygen-, carbon-, and nitrogen-containing reactants may be delivered to the a-Si layer to form a silicon oxycarbonitride layer.

In one example, a silicon nitride may be obtained from the a-Si layer by providing one or more nitrogen-containing source gases such as nitrogen (N₂), ammonia (NH₃), diazene (N₂H₂), hydrazine (N₂H₄), or combinations thereof to a remote plasma source such that nitrogen radicals are supplied to the a-Si layer. In another example, one or more carbon-containing reactants (e.g., hydrocarbons) such as acetylene (C₂H₂), ethylene (C₂H₄), propene (C₃H₆), or combinations thereof may be supplied to the a-Si layer to obtain a silicon carbide layer. The resulting silicon nitride layer or silicon carbide layer does not necessarily include any unwanted phase such as silicon oxide layer as evidenced from qualitative analysis such as a Fourier-Transform infrared spectroscopy (FTIR).

When it is desirable to achieve a doped silicon layer doped with two or more dopants, two or more different source gases may be supplied to the plasma source to generate radical species containing different gas species. For example, carbon- and nitrogen-containing reactants may be supplied to convert the a-Si layer to a doped silicon layer doped with carbon and silicon. The relative amounts of carbon-silicon bonds to nitrogen-silicon bonds in a doped silicon layer may decide the composition of a doped silicon (e.g., silicon carbonitride) layer. The relative amounts of carbon-silicon bonds and nitrogen-silicon bonds may be determined by compositions and flow rates of source gases, pressure, conversion time, RF power, or the like. In one example, plasma conditions such as RF power and/or frequency may be tuned to have oxygen doped silicon carbide layers with different amounts of oxygen, or nitrogen and oxygen doped silicon carbide layers with different amounts of nitrogen.

In some embodiments, a composition of one or more source gases in the remote plasma may be controlled to tune a composition of the doped silicon layer. For example, the ratio of flow rate of oxygen or oxide reactants such as oxygen (O₂), water (H₂O), carbon monoxide (CO), carbon dioxide (CO₂), nitrous oxide (N₂O), nitrogen dioxide (NO₂), or combinations thereof to carbon-containing reactants such as acetylene (C₂H₂), ethylene (C₂H₄), propene (C₃H₆) may be selected to be about (0.01-0.2):1, or about (0.05-1):1, or about 0.1:1 to obtain a silicon oxy carbide including about 1-50% of carbon (C), and about 1-50% of oxygen (O).

In yet another example, for forming a silicon carbonitride layer, the ratio of the flow rate for carbon-containing reactants (e.g., hydrocarbons) such as acetylene (C₂H₂), ethylene (C₂H₄), propene (C₃H₆), or combinations thereof to nitrogen-containing reactants such as nitrogen (N₂), ammonia (NH₃), diazene (N₂H₂), hydrazine (N₂H₄), or combinations thereof may be selected to be about (0.01-1):1 or about (0.05-1):1, or about (0.1-1):1, or about (0.5-1):1 to convert an a-Si layer to a silicon carbonitride layer including about 1-40% of carbon (C), about 5-45% of nitrogen (N). The resulting silicon carbonitride layer may be formed without introducing any unwanted oxide phase during the conversion, thereby preventing deterioration in electrical properties for use in a semiconductor device.

In still yet another example, for forming a silicon oxynitride layer, a ratio of the flow rate for oxygen or oxide reactants such as oxygen (O₂), water (H₂O), carbon monoxide (CO), carbon dioxide (CO₂), nitrous oxide (N₂O), nitrogen dioxide (NO₂), or combinations thereof to nitrogen-containing reactants such as nitrogen (N₂), ammonia (NH₃), diazene (N₂H₂), hydrazine (N₂H₄), or combinations thereof may be about (0.01-0.7):1, or about (0.02-0.5):1, or about (0.04-0.4):1 to convert an a-Si layer to a silicon oxynitride layer including about 1-50% of oxygen (O), and about 5-40% of nitrogen (N).

In yet another example, for forming a silicon oxycarbonitride layer, a ratio of the flow rate for oxygen or oxide reactants such as oxygen (O₂), water (H₂O), carbon monoxide (CO), carbon dioxide (CO₂), nitrous oxide (N₂O), nitrogen dioxide (NO₂), or combinations thereof to carbon-containing reactants (e.g., hydrocarbons) such as acetylene (C₂H₂), ethylene (C₂H₄), propene (C₃H₆), or combinations thereof to nitrogen-containing reactants such as nitrogen (N₂), ammonia (NH₃), diazene (N₂H₂), hydrazine (N₂H₄), or combinations thereof may be selected to be about (0.01-10):(1-10):10, or about (0.01-7):(1-8):10, or about (0.01-5):(1-5):10 (oxygen source:carbon source:nitrogen source) to obtain a silicon oxycarbonitride layer including about 1-20% of carbon (C), about 1-30% of nitrogen (N), and about 1-40% of oxygen (O).

In some embodiments of the present disclosure, a conformal silicon layer may be converted to a doped silicon layer. In some embodiments, the conformal silicon layer is a conformal amorphous silicon layer. One or more source gases including one or more of nitrogen, oxygen, hydrogen, or carbon may be supplied to the remote plasma source to generate a gas plasma flow including radical species and/or ions of one of more of nitrogen, oxygen, hydrogen, or carbon. The gas plasma flow may be generated in the remote plasma source that is separated from the reaction chamber. A remote plasma flow including the gas plasma flow may be introduced into the reaction chamber through the showerhead toward the surface of the substrate to convert the conformal silicon layer to the doped silicon layer. The doped silicon layer may be conformal.

The pressure in the reaction chamber at operation 106 may be adjusted to increase ionization of the one or more gas species in the source gases and reduce residence times of the radicals. Reduced residence times will reduce the effects of recombination of the radicals. A lower pressure allows molecules to move faster, which results in increased ionization of the source gas, reduced residence times, and reduced recombination of radicals. In some embodiments, the pressure can be between about 0.2 Torr and about 10 Torr, or between about 1 Torr and about 3 Torr. However, it will be understood that the pressure in the reaction chamber during the exposure to a gas plasma flow can be greater than 3 Torr or greater than 10 Torr where other process conditions (e.g., inert carrier gas) cause sufficient ionization and reduced residence times.

The a-Si layer on the substrate may be exposed to the gas plasma flow for a predetermined time. In some embodiments, the predetermined time can be between about 2 seconds and about 100 seconds, or between about 5 seconds and about 50 seconds. Determination of the treatment time may depend on the thickness of the a-Si layer, where thicker layers may require longer time to be exposed to the gas plasma flow.

In addition to time and pressure during the exposure to the gas plasma flow, one or more process conditions may be controlled by tuning one or more of RF power, source gas flow, source gas composition, and other process conditions may be tuned at operation 106 to influence the characteristics of the remote plasma, which can thereby result in different bond density in the a-Si layer prior to or during the conversion.

Deposition and conversion of the a-Si layer may be achieved with one cycle of deposition and conversion. Alternatively, deposition (operation 104) and conversion (operation 106) of an a-Si layer can be achieved with alternating deposition and conversion cycles. Deposition and conversion may occur in a layer-by-layer approach to allow for each plasma conversion cycle to fully convert the deposited a-Si layer such that substantially the entirety of the deposited a-Si layer is doped with radical species. That way, the entire a-Si layer stack can be uniformly converted to a doped silicon layer, and have a more uniform distribution of gas species across the thickness of a doped silicon layer. Therefore, it will be understood that deposition and conversion cycles in the formation of the doped silicon layer may continue to repeat until a desired doped silicon layer thickness is achieved at operation 108.

For some embodiments, conversion of the a-Si layer to the doped silicon layer may occur substantially simultaneously with exposing the a-Si layer to the gas plasma flow including one or more radical species. In some embodiments, the radical species from one or more source gases are supplied to the surface of the a-Si layer, where a bond between silicon and a gas species such as carbon, oxygen, hydrogen, or nitrogen may form. For forming nitrogen doped silicon layer, nitrogen radicals in a gas plasma flow may be adsorbed to the surface of a-Si surface. Then, one or more nitrogen radicals may displace silicon atoms that are bonded with neighboring silicon atoms in an a-Si. An a-Si is a continuous random network of silicon atoms where long range order is not present and not all silicon atoms have fourfold coordination. An a-Si layer may have short range order of silicon atoms, and the bonding energy between neighboring silicon atoms may not be high compared to silicon-silicon bonds in a crystalline silicon. A small percentage of the silicon atoms may be hydrogenated. Subsequently, nitrogen radicals may insert into Si atom network and form a Si—N bond. That way, nitrogen radicals from a gas plasma flow may be a source for dopants for an a-Si layer, forming a Si—N bond in an a-Si layer. In case an a-Si layer is doped by two different dopants such as nitrogen and carbon, a gas plasma flow including carbon and nitrogen radicals may be transported to the surface of a-Si layer, where the bonds between silicon atoms may be broken and carbon or nitrogen atoms will insert into silicon network. Subsequently, Si—C bonds and Si—N bonds will be formed. The dopant density in an a-Si may depend on parameters such as duration of a gas plasma flow on the substrate, reactant gas flow and concentration, a plasma power, a pressure in the reaction chamber, temperature in the reaction chamber. For example, the number of silicon-dopant bonds may increase in proportion to duration of a gas plasma flow on the substrate.

During the conversion from an a-Si layer to a doped silicon layer, the temperature in the environment adjacent to the substrate can be any suitable temperature facilitating the conversion reaction by doping one or more gas species into the a-Si layer, but sometimes limited by the application of the device containing a doped silicon layer. In some embodiments, the temperature in the environment adjacent to the substrate can be largely controlled by the temperature of a pedestal on which a substrate is supported during a plasma treatment. In some embodiments, the operating temperature can be between about 50° C. and about 650° C. For example, the operating temperature can be between about 250° C. and about 400° C. in many integrated circuit applications. In some embodiments, increasing the temperature may lead to increased number of bonds between silicon atoms and dopant atoms, while reducing the number of Si—Si bonds. Increasing the temperature may also lead to increased crystallinity of a doped silicon layer.

In some embodiments, an amorphous boron (a-B) may also be converted to a doped boron layer. The a-B layer may be deposited by a suitable deposition method including PVD, CVD, LPCVD, PECVD, hot-wire CVD, ALD, or PEALD. In some embodiments, the a-B layer is deposited by flowing one or more boron-containing precursors to adsorb on a surface of the substrate, and thermally decomposing the one or more boron-containing precursors to form the a-B layer. The a-B layer may by exposed to a gas plasma flow including one or more radical species described herein to convert to the a-B layer to a doped boron layer. In some embodiments, the a-B layer is exposed to a remote plasma flow. Specifically, the exposure to remote plasma flow involves at least generating a remote plasma of a source gas in a remote plasma source that is separate from the reaction chamber, and introducing the remote plasma as the remote plasma flow through a showerhead into the reaction chamber. The source gas may include nitrogen-containing reactants, hydrogen-containing reactants, hydrocarbons, oxygen or oxide reactants, or combinations thereof. From exposure to the gas plasma flow, the a-B layer is converted to the doped boron layer. The doped boron layer may include boron carbide, boron nitride, boron oxide, boron oxynitride, boron oxycarbide, boron carbonitride, or boron oxycarbonitride.

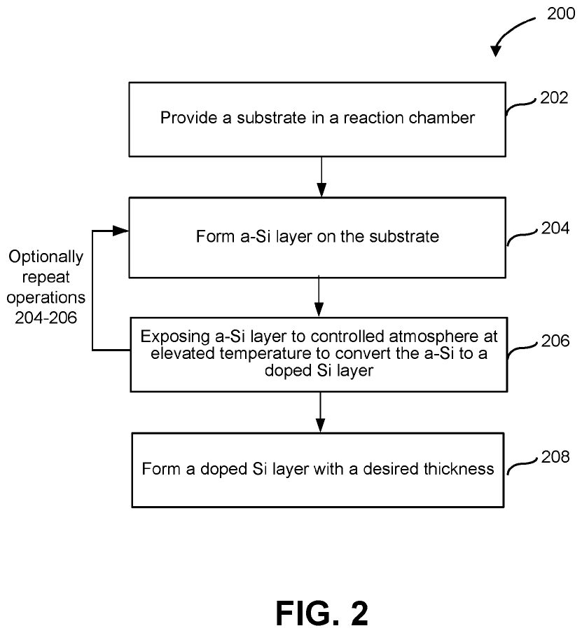

In some embodiments, an a-Si layer or an a-B layer may be converted to a doped silicon layer or a doped boron layer, respectively, by exposing to one or more gas species described herein in a controlled environment at an elevated temperature. This can be done with or without exposure to plasma. FIG. 2 presents a process flow diagram 200 for forming a doped silicon layer according to some embodiments. While the diagram 200 is described for forming a doped silicon layer by a thermal conversion, it is to be understood that the diagram 200 may also be applied in converting an a-B layer to a doped boron layer. In operation 202, a substrate is provided in a reaction chamber. In some embodiments, the substrate is a semiconductor substrate. In operation 204, an a-Si layer may be formed on the substrate by a suitable deposition process as described herein. In some embodiments, the a-Si layer may be deposited by flowing one or more silicon-containing precursors to adsorb on a surface of the substrate, and thermally decomposing the one or more silicon-containing precursors to form the a-Si layer. The a-Si layer may be highly conformal. After deposition, a step coverage for the a-Si layer may be at least 85%, at least 90%, or at least 98%. In operation 206, the a-Si layer may be exposed to a controlled atmosphere at an elevated substrate temperature. For example, the a-Si layer may be exposed to one or more source gases including nitrogen, oxygen, hydrogen, carbon, or combinations thereof. The substrate temperature be equal to or greater than about 200° C., or may range between about 200° C. and about 650° C. The substrate on the pedestal may be heated up by controlling one or more heating elements in the pedestal. The substrate may be heated to a desirable temperature before one or more gas species are provided to the substrate surface. The atmosphere may be controlled to include one or more gas species to arrive and react with the a-Si layer on the substrate. After a predetermined time period at an elevated temperature, a-Si layer may be converted to a doped silicon layer. The doped silicon layer may be partially crystallized or fully crystallized. As such, the doped silicon layer may be a crystallized silicon-containing layer. The operations 204 and 206 may be repeated until the doped silicon layer is formed with a desired thickness at operation 208. At operation 208, the doped silicon layer may be a stack of the doped silicon layers partially or fully crystallized. Though the process flow diagram 200 is illustrated for converting an a-Si layer to a doped silicon layer, it will be understood that the a-Si layer may be substituted with an a-B layer and the doped silicon layer may be substituted with a doped boron layer.

In some embodiments, the composition of the doped layer may be determined by the composition and flow rate of one or more source gases. The doped silicon layer may include silicon oxide, silicon nitride, silicon carbide, silicon oxycarbide, silicon oxynitride, silicon carbonitride, or silicon oxycarbonitride. A doped boron layer may include boron carbide, boron nitride, boron oxide, boron oxynitride, boron oxycarbide, boron carbonitride, or boron oxycarbonitride.

In thermal conversion, gas species may be dissociated to generate free atoms or gas molecules. For example, in forming boron nitride (BN), free atom (N) and/or gas molecule (N₂) may be doped to an a-B layer to form a boron nitride layer. The conversion may be initiated from the outermost layer of an amorphous layer, converting an amorphous layer to an at least partially crystallized layer. A doped silicon or a doped boron layer thickness on a substrate may be adjusted by controlling time period for the thermal conversion.

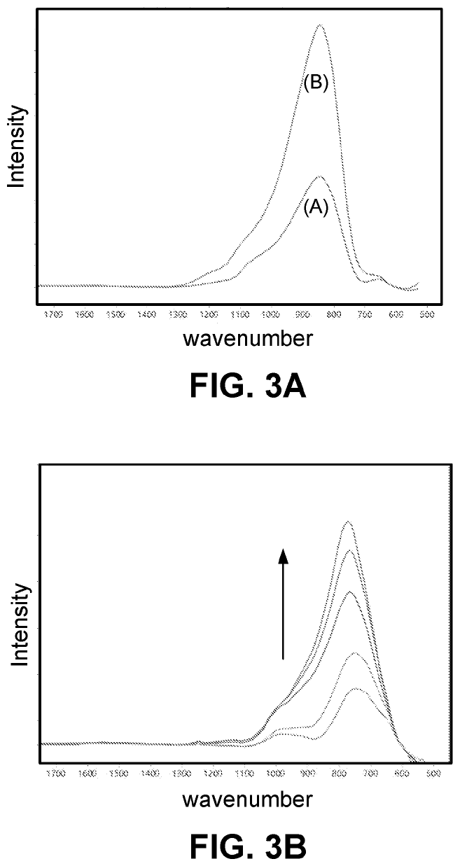

FIG. 3A shows a graph of Fourier-Transform infrared spectroscopy (FTIR) absorption spectra with vibration peaks for detecting bond type in silicon nitride layer treated under different conditions. FIG. 3A shows two Si—N peaks with different intensities, both showing the formation of Si—N bonds for silicon nitride. An increase in Si—N peak intensity (B) is likely to result from an increase in nitrogen containing radicals and/or ions that impinge to the surface of a-Si layer compared to Si—N peak (A). That is, higher peak intensity may correspond to more Si—N bonds per volume. Increased carbon containing radicals and/or ions may be obtained by controlling various parameters such as plasma power (current and/or voltage), treatment time duration, source gas flow rate etc. For example, with increase in plasma power, more nitrogen containing radicals may impinge and dope an a-Si layer. FIG. 3B shows Fourier-Transform infrared spectroscopy (FTIR) absorption spectra with vibration peaks for detecting bond type in a silicon carbide layer treated under different treatment conditions. Similar to the silicon nitride layer shown in FIG. 3A, an increased Si—C peak intensity in FIG. 3B (in an arrow direction) corresponds to increased Si—C bond density in a silicon carbide layer treated by a remote plasma source.

The conversion of an a-Si layer to a doped silicon layer according to some embodiments may have following advantages. The resulting doped silicon layer according to some embodiments may form a conformal layer that is desirable for manufacturing a HAR features in a semiconductor device. Compositional tunability in a treated silicon layer doped with two or more dopants is also possible. For example, silicon oxide may be thermodynamically stable and may be typically formed during silicon-based layer deposition. On the other hand, according to some embodiments, formation of silicon oxide phase formation in a doped silicon layer may be controlled depending on the desired composition of doped silicon. Further, forming a doped silicon layer according to some embodiments of the present disclosure has a throughput faster than conventional ALD process.

The methods described herein may also be used on memory arrays utilized for programmable data storage. For instance, dynamic random-access memory (DRAM) is commonly utilized for programmable memory storage. The DRAM will typically be formed as an array of individual memory cells, with each cell comprising a transistor and a memory storage device. The memory storage devices will typically be capacitors. The transistors will be formed within wordlines which extend across the DRAM array. A series of bitlines will also be provided across the DRAM array. Bits of information are written to, or read from, a memory storage device of an individual DRAM cell by activating a specific combination of a wordline and a bitline. Accordingly, each memory device of the DRAM array can be specifically addressed with the appropriate combination of a wordline and a bitline.

In the production of DRAM applications, deposition processes may be used to form a bitline interconnect made of an electrically conductive material. The electrically conductive material may be formed over a semiconductor material such as polysilicon. In some embodiments, the electrically conductive material is shaped into electrically conductive lines by formation within trenches. After the bitline interconnect is formed, an insulative cap can be formed over the bitline interconnect. The electrically conductive lines or bitlines may be separated from one another by at least dielectric spacer material.

Though some aspects described herein can be particularly useful in fabrication of DRAM arrays, it is to be understood that the present disclosure is not limited to DRAM arrays. The present disclosure of can be applied to other semiconductor fabrication processes as will be recognized by persons of ordinary skill in the art.

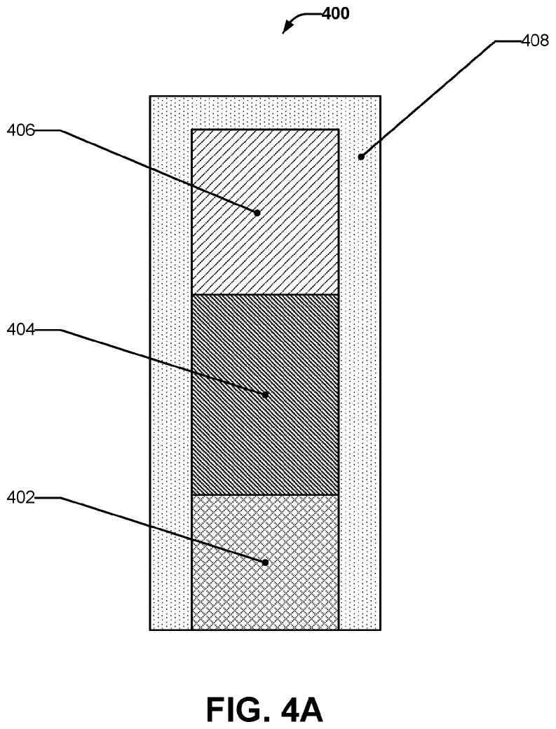

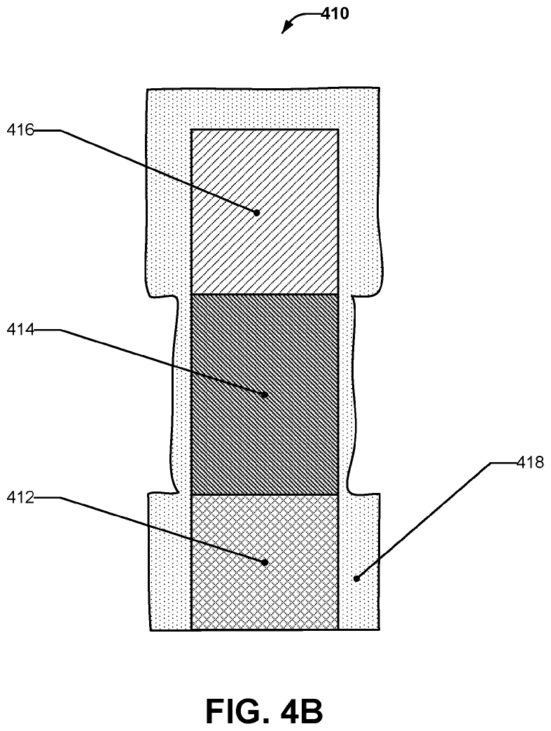

FIG. 4A shows a cross-sectional schematic illustration of an example semiconductor device structure having a spacer layer uniformly deposited on a dielectric capping layer and an electrically conductive layer of the semiconductor device structure. A semiconductor device structure 400 may be part of a memory device such as a DRAM array. In some cases, the semiconductor device structure 400 may be a bitline interconnect structure in a DRAM array. The semiconductor device structure 400 may include a stack of materials that is formed on a semiconductor substrate. The stack may include a semiconductor layer 402, an electrically conductive layer 404 over the semiconductor layer 402, and a dielectric capping layer 406 over the electrically conductive layer 404. The semiconductor layer 402 may be composed of polysilicon or other suitable semiconductor material. The electrically conductive layer 404 may include an electrically conductive material such as tungsten (W), tantalum (Ta), titanium (Ti), molybdenum (Mo), hafnium (Hf), cobalt (Co), chrome (Cr), nickel (Ni), platinum (Pt), ruthenium (Ru), copper (Cu), aluminum (Al), or alloys thereof. In some embodiments, the electrically conductive layer 404 includes tungsten or tungsten nitride. In some embodiments, the electrically conductive layer 404 includes tungsten or molybdenum. As used herein, an electrically conductive layer comprises any material having a resistivity of 1×10⁻⁵ Ω-m or less at room temperature. The electrically conductive layer 404 may function as a bitline conductive layer. The dielectric capping layer 406 may include an electrically insulating material such as a nitride or oxide. Examples include silicon nitride (Si₃N₄), silicon oxide (SiO₂), aluminum oxide (Al₂O₃), or combinations thereof. Other examples include amorphous carbon (a-C) hard masks or silicon-based hard masks such as silicon carbide (SiC) or silicon oxycarbide. In some embodiments, the dielectric capping layer 406 includes silicon nitride. The dielectric capping layer 406 may function as a bitline hard mask.

The stack of the semiconductor layer 402, the electrically conductive layer 404, and the dielectric capping layer 406 may be formed as a non-planar feature or vertical structure on the semiconductor substrate. A spacer layer 408 may be deposited on the semiconductor device structure 400 including exposed surfaces of the semiconductor layer 402, the electrically conductive layer 404, and the dielectric capping layer 406. The spacer layer 408 may also be referred to as an encapsulation layer or encapsulation film. In some embodiments, the spacer layer 408 includes a low-k dielectric material, where the low-k dielectric material has a dielectric constant equal to or less than about 5.0. In some embodiments, the spacer layer 408 includes a silicon-containing material, such as a silicon nitride film, a silicon carbide film, a silicon oxide film, a silicon oxycarbide film, or silicon carbonitride film. For example, the spacer layer 408 may be composed of silicon oxycarbide film, where the silicon oxycarbide film may have a dielectric constant between about 2.5 and about 4.5 or between about 3.5 and about 4.4.

The spacer layer 408 may be conformally deposited on the semiconductor device structure 400. Conformal deposition of the spacer layer 408 results in relatively uniform deposition of the spacer layer 408 on sidewalls and a top surface of the semiconductor device structure 400. Conformal deposition may be performed using any suitable deposition technique such as atomic layer deposition (ALD) or chemical vapor deposition (CVD). As such, the spacer layer 408 may be substantially uniformly deposited on the electrically conductive layer 404 and the dielectric capping layer 406. Uniform deposition of the spacer layer 408 on the semiconductor device structure 400 such as a memory device structure is increasingly important as device dimensions shrink and aspect ratios become increasingly higher.

However, a spacer layer may be non-uniformly deposited on a dielectric capping layer relative to an electrically conductive layer due to the effects of nucleation delay. The growth of certain spacer materials may have a different nucleation delay on dielectric surfaces such as silicon nitride than on electrically conductive surfaces such as tungsten. The difference in nucleation delay causes different amounts of material growth on dielectric surfaces relative to electrically conductive surfaces. In fact, when depositing a spacer material such as silicon oxycarbide, there is more nucleation delay on tungsten surfaces than on silicon nitride surfaces. This can occur even when applying a conformal deposition technique such as ALD.

FIG. 4B shows a cross-sectional schematic illustration of an example semiconductor device structure having a spacer layer non-uniformly deposited on a dielectric capping layer and an electrically conductive layer of the semiconductor device structure due to the effects of nucleation delay. A semiconductor device structure 410 may be part of a memory device such as a DRAM array. In some cases, the semiconductor device structure 410 may be a bitline interconnect structure in a DRAM array. The semiconductor device structure 410 may include a stack of materials formed on a semiconductor substrate. The stack may include a semiconductor layer 412, an electrically conductive layer 414 over the semiconductor layer 412, and a dielectric capping layer 416 over the electrically conductive layer 414.

The stack of the semiconductor layer 412, the electrically conductive layer 414, and the dielectric capping layer 416 may be formed as a non-planar feature or vertical structure on the semiconductor substrate. A spacer layer 418 may be deposited on the semiconductor device structure 410 including exposed surfaces of the semiconductor layer 412, the electrically conductive layer 414, and the dielectric capping layer 416. In some embodiments, the spacer layer 418 includes a low-k dielectric material such as silicon oxycarbide. The spacer layer 418 may be deposited on exposed surfaces of the electrically conductive layer 414 such as tungsten and exposed surfaces of the dielectric capping layer 416 such as silicon nitride, where an average thickness of the spacer layer 418 on the dielectric capping layer 416 is greater than an average thickness of the spacer layer 418 on the electrically conductive layer 414. Even if the spacer layer 418 is deposited using a conformal deposition technique such as ALD, the effects of nucleation delay may result in non-uniform deposition of the spacer layer 418 on the dielectric capping layer 416 relative to the electrically conductive layer 414. In some embodiments, the effects of nucleation delay may alternatively or additionally result in non-uniform deposition of the spacer layer 418 on the semiconductor layer 412 relative to the electrically conductive layer 414. Accordingly, the deposition rate of the spacer layer 418 on the electrically conductive layer 414 is slower relative to one or both of the dielectric capping layer 416 and the semiconductor layer 412. In some cases, this may be due in part to the slowness of nucleation on tungsten surfaces. Not only does nucleation delay lead to non-uniform deposition of spacer material on the semiconductor device structure 400, but nucleation delay may ultimately lead to reduced device performance and even device failure.

To mitigate the effects of nucleation delay for certain spacer materials, an initiation layer may be deposited on exposed surfaces of a dielectric capping layer and an electrically conductive layer. In some cases, the initiation layer may also be deposited on exposed surfaces of a semiconductor layer. The initiation layer may be a thin or ultrathin layer that is conformally deposited on the stack including at least the dielectric capping layer and the electrically conductive layer to provide a uniform and consistent surface on which spacer material can be grown. In other words, the spacer material can grow uniformly on the initiation layer because the surface on which the spacer material is grown is the same.

Not all types of initiation layers perform equally. Some initiation layers may still lead to uneven growth of spacer material over a dielectric capping layer relative to an electrically conductive layer. For example, depositing silicon oxycarbide as a spacer material on a silicon dioxide initiation layer may still lead to more deposition (i.e., greater thickness) over a silicon nitride capping layer relative to a tungsten electrically conductive layer. Thus, some silicon dioxide initiation layers may not sufficiently mitigate the effects of nucleation delay. Additionally, some initiation layers may reduce electrical performance in the electrically conductive layer. By way of an example, depositing silicon oxycarbide as a spacer material on a silicon nitride initiation layer may sufficiently mitigate the effects of nucleation delay, but the silicon nitride initiation layer may degrade the electrical performance of a tungsten electrically conductive layer due to nitridation.

In addition to the performance limitations of certain initiation layers, conformal deposition techniques such as ALD may be slow and decrease throughput. As device structures shrink and high aspect ratio features become prevalent in the semiconductor industry, the capability of depositing conformal films will continue to gain importance. ALD is a film forming technique well-suited to deposition of conformal films. ALD uses surface-mediated deposition reactions to deposit films on a layer-by-layer basis. While ALD can achieve a highly conformal initiation layer in high aspect ratio features, ALD may be too slow to obtain a desired thickness compared to other deposition techniques.

The present disclosure relates to conformal deposition of an initiation layer, where the initiation layer may be amorphous silicon, amorphous boron, doped silicon, or doped boron. The doped silicon may be converted from the amorphous silicon, and the doped boron may be converted from the amorphous boron. An initiation layer is a layer that is deposited on at least two different materials so that a subsequent material is grown on the same material surface. The amorphous silicon or amorphous boron is conformally deposited by CVD such as thermal CVD. The amorphous silicon or amorphous boron is deposited on one or more semiconductor device structures of a semiconductor substrate, where each semiconductor device structure comprises at least a dielectric layer on an electrically conductive layer. In some embodiments, each semiconductor device structure further comprises a semiconductor layer, where the electrically conductive layer is formed on the semiconductor layer. In some embodiments, the one or more semiconductor device structures are memory device structures, where the electrically conductive layer comprises tungsten or molybdenum and the dielectric layer comprises silicon nitride. A spacer layer is deposited on the initiation layer, where the spacer layer may be deposited substantially uniformly over the dielectric layer and the electrically conductive layer of each semiconductor device structure. Deposition of the spacer layer and the amorphous silicon or amorphous boron may occur in the same processing chamber, where the spacer layer and the amorphous silicon or amorphous boron are deposited by CVD-based processes. In some embodiments, the amorphous silicon serves as the initiation layer. In some other embodiments, the doped silicon serves as the initiation layer, where the doped silicon is formed by exposing the amorphous silicon with plasma to convert the amorphous silicon to silicon carbide, silicon oxycarbide, silicon carbonitride, or silicon oxycarbonitride. In some embodiments, the amorphous boron serves as the initiation layer. In some other embodiments, the doped boron serves as the initiation layer, where the doped boron is formed by exposing the amorphous boron with plasma to convert the amorphous boron to boron carbide, boron nitride, boron oxide, boron oxynitride, boron oxycarbide, boron carbonitride, or boron oxy carbonitride.

The initiation layer of the present disclosure offers many advantages. Particularly, the initiation layer provides an improved surface for growth of spacer materials such as low-k dielectric spacer materials (e.g., silicon oxycarbide). That way, the low-k dielectric spacer materials can be deposited relatively uniformly over dielectric materials and electrically conductive materials. The initiation layer also does not degrade electrical performance of underlying electrically conductive materials such as tungsten. Moreover, the initiation layer of the present disclosure may be deposited conformally at a faster deposition rate than conventional conformal deposition techniques such as ALD.

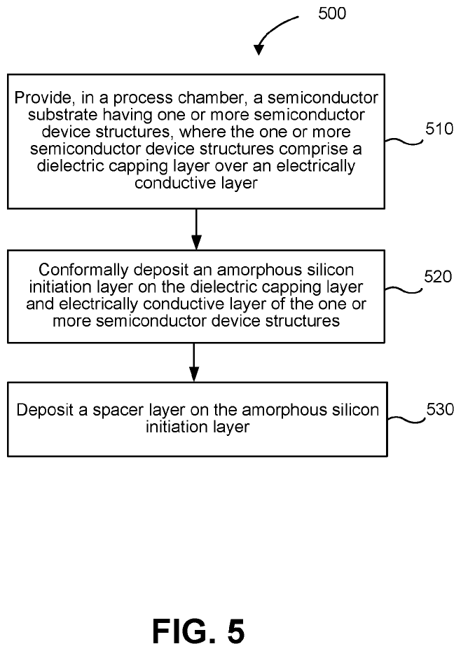

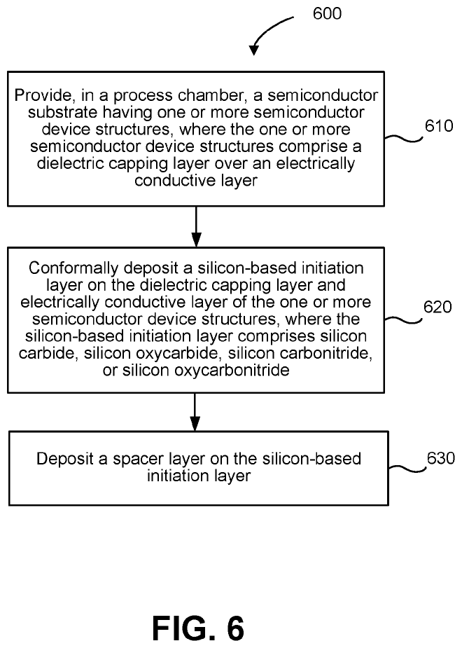

In some embodiments of the present disclosure, the initiation layer disposed on one or more semiconductor device structures for deposition/growth of spacer material is conformal amorphous silicon, which is described in a process flow in FIG. 5. In alternative embodiments of the present disclosure, the initiation layer disposed on one or more semiconductor device structures for deposition/growth of spacer material is conformal doped silicon rather than conformal amorphous silicon, which is described in a process flow in FIG. 6. In some other alternative embodiments of the present disclosure, the initiation layer disposed on one or more semiconductor device structures for deposition/growth of spacer material is conformal amorphous boron or conformal doped boron.

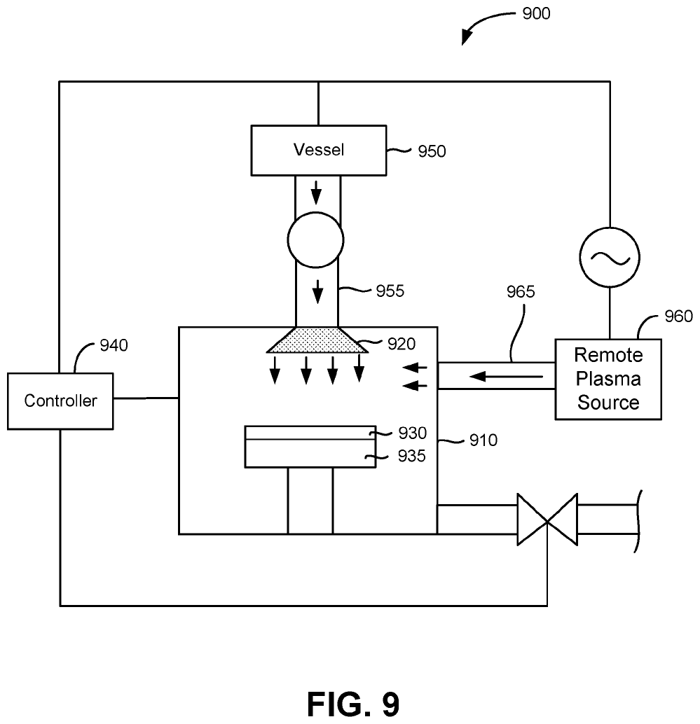

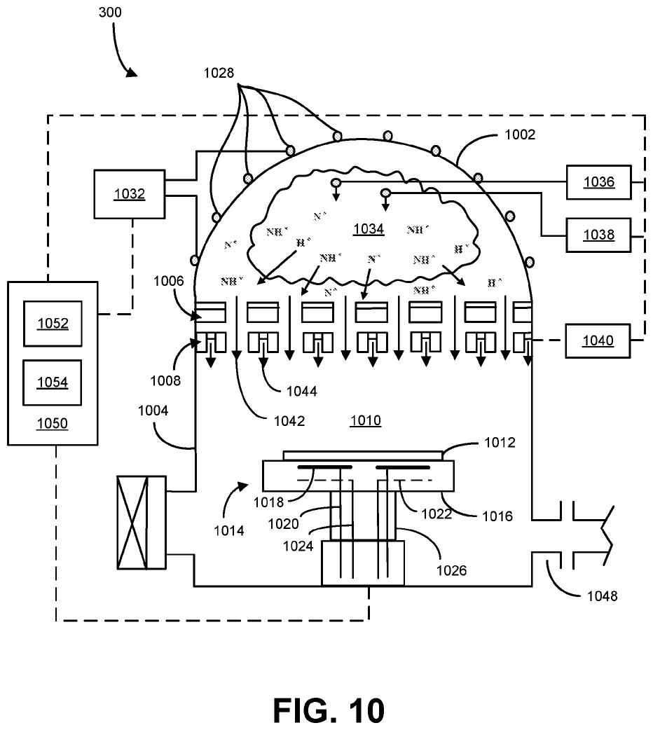

FIG. 5 illustrates a flow chart of an example method of forming a spacer layer on one or more semiconductor device structures according to some embodiments. The operations of a process 500 may be performed in different orders and/or with different, fewer, or additional operations. One or more operations of the process 500 may be performed using a substrate processing apparatus shown in FIG. 9 or 10. In some embodiments, the operations of the process 500 may be implemented, at least in part, according to software stored in one or more non-transitory computer readable media.

At block 510 of the process 500, a semiconductor substrate is provided having one or more semiconductor device structures, where each of the semiconductor device structures comprises at least a dielectric capping layer over an electrically conductive layer. In some embodiments, each of the semiconductor device structures comprises a semiconductor layer such as polysilicon, where the electrically conductive layer is positioned over the semiconductor layer. The semiconductor substrate is provided in a process chamber. The semiconductor substrate may be supported on a substrate support or pedestal in the process chamber. The semiconductor substrate may be a patterned substrate having one or more features. The one or more features may be high aspect ratio features, where the high aspect ratio features have a depth to width aspect ratio equal to or greater than about 10:1, equal to or greater than about 15:1, equal to or greater than about 20:1, equal to or greater than about 25:1, equal to or greater than about 30:1, equal to or greater than about 40:1, equal to or greater than about 50:1, or equal to or greater than about 100:1. In some instances, each of the one or more features may be recessed features formed between pairs of the semiconductor device structures. For some embodiments, the one or more recessed features include high aspect ratio trenches in 3D-NAND.

The process chamber provides an enclosed space for depositing an initiation layer on the semiconductor substrate. In some cases, the process chamber is also used for depositing a spacer layer on the initiation layer. Using the same process chamber for deposition of the initiation layer and subsequent spacer layer minimizes substrate transfers and air breaks in between operations. Chamber walls in the process chamber may be fabricated from stainless steel, aluminum, plastic, ceramic, or other suitable material. The process chamber may include a substrate support (e.g., pedestal or electrostatic chuck) on which the semiconductor substrate is supported. In some embodiments, the process chamber may include one or more heating elements for controlling a temperature of the substrate, where the one or more heating elements may be infrared (IR) lamps light-emitting diodes (LEDs), or resistive heaters located in the substrate support. The process chamber may include one or more gas lines for delivering gas into the process chamber. For example, the one or more gas lines may include a showerhead for supplying process gases towards the semiconductor substrate in the process chamber. In some embodiments, the process chamber may be coupled to a plasma-generating chamber separate from the process chamber. The plasma-generating chamber (e.g., remote plasma chamber) may be an inductively-coupled plasma (ICP) reactor, a transformer-coupled plasma (TCP) reactor, or a capacitively-coupled plasma (CCP) reactor. In some cases, the process chamber further includes one or more gas outlets for exhausting gases, which may or may not be coupled to a vacuum pump to maintain a desired pressure within the process chamber. In some embodiments, the process chamber for depositing amorphous silicon may be the same for converting amorphous silicon to a doped silicon layer.

In some embodiments, the electrically conductive layer may include an electrically conductive material such as tungsten, tantalum, titanium, molybdenum, hafnium, cobalt, chrome, nickel, platinum, ruthenium, copper, aluminum, or alloys thereof. For example, the electrically conductive layer includes tungsten or tungsten nitride, or the electrically conductive layer includes tungsten or molybdenum. In some embodiments, the dielectric capping layer may include an electrically insulating material such as nitride or oxide. For instance, the dielectric capping layer may include silicon nitride, silicon oxide, aluminum oxide, silicon carbide, silicon oxycarbide, amorphous carbon, or combinations thereof.

In some embodiments, the one or more semiconductor device structures include memory device structures that are part of a memory array. For instance, the one or more semiconductor device structures are DRAM bit structures that are part of a DRAM array. The DRAM bit structures may be vertically-oriented structures having at least a bitline. The DRAM bit structures may further include a capping layer such as a nitride capping layer on the bitline, where the capping layer serves to cover and isolate the bitlines. The capping layer may also function as a bitline hard mask. The DRAM bit structures may further include a semiconductor layer such as polysilicon underlying the bitline, where the bitline is electrically coupled to a transistor at the semiconductor layer. The DRAM bit structures may comprise multiple vertically-oriented structures in a DRAM array with at least a bitline as an electrically conductive layer, a capping layer as a dielectric capping layer over the bitline, and a semiconductor layer underlying the bitline. The DRAM bit structures may be spaced apart by recessed features such as trenches, where the recessed features may have a depth to width aspect ratio equal to or greater than about 10:1, equal to or greater than about 20:1, or equal to or greater than about 50:1.

At block 520 of the process 500, an amorphous silicon initiation layer is conformally deposited on the dielectric capping layer and electrically conductive layer of the one or more semiconductor device structures. Amorphous silicon (a-Si), as opposed to crystalline silicon, is non-crystalline and lacks long-range order. An “initiation layer” is a thin or ultrathin layer of material that is formed on at least two different material surfaces to provide a single material surface for deposition thereon. A thin layer can be defined as a layer having a thickness equal to or less than about 500 Å, and an ultrathin layer can be defined as a layer having a thickness equal to or less than about 50 Å. For example, the amorphous silicon initiation layer can have a thickness equal to or less than about 100 Å, equal to or less than about 50 Å, or between about 2 Å and about 30 Å. The amorphous silicon initiation layer is a thin or ultrathin layer of amorphous silicon deposited conformally on at least two different material surfaces and serves as a single material surface on which a subsequent layer (e.g., spacer layer) is deposited thereon.

The amorphous silicon initiation layer may be deposited on the one or more semiconductor device structures by CVD, PECVD, ALD, PEALD, or other suitable deposition technique. In some embodiments, the amorphous silicon initiation layer is deposited by CVD via a thermal decomposition process. The thermal decomposition process is initiated by activation of precursor gas species at elevated temperatures, where the precursor gas species breaks down thermally into atoms and/or molecules for deposition by CVD.

In some embodiments, a thickness of the amorphous silicon initiation layer can be controlled according to a predetermined deposition time to achieve a desired thickness. In some embodiments, the deposition time can be between about 5 seconds and about 500 seconds, or between about 10 seconds and about 200 seconds. In some embodiments, a desired thickness of the amorphous silicon initiation layer can be between about 1 Å and about 1000 Å, between about 2 Å and about 50 Å, or between about 2 Å and about 30 Å. The deposition time can correspond to the desired thickness of the amorphous silicon initiation layer. The thickness may be controlled to enable sufficient penetration of radicals and/or ions in the amorphous silicon initiation layer from a subsequent remote plasma treatment.

For some embodiments, deposition of the amorphous silicon initiation layer can occur by flowing one or more silicon-containing precursors into the process chamber towards the semiconductor substrate. The silicon-containing precursors are transported to the substrate surface where they are adsorbed by the semiconductor substrate to form a highly conformal amorphous silicon initiation layer. In some embodiments, forming an amorphous silicon initiation layer by CVD may necessitate controlling the deposition pressure ranging from 0.1 Torr to 30 Torr or from 0.5 Torr and about 10 Torr. Substrate temperature during amorphous silicon deposition may be controlled to be between about 300° C. and about 700° C., between about 400° C. and about 650° C., or between about 450° C. and about 600° C. After deposition, a step coverage for the amorphous silicon initiation layer may be at least about 85%. In some embodiments, a step coverage may be at least about 90%, at least about 95%, or at least about 98%. As used herein, step coverage may be calculated by comparing the average thickness of a deposited film on a bottom, sidewall, or top of a feature against the average thickness of the deposited film on another part of the feature. For example, step coverage may be calculated by dividing the average thickness of the deposited film on the sidewall against the average thickness of the deposited film at the top of the feature, and multiplying by 100 to obtain a percentage.

For some embodiments in CVD or PECVD, silicon-containing precursors may be continuously delivered to the semiconductor substrate until a desired thickness is obtained. In other embodiments in ALD or PEALD, an amorphous silicon initiation layer may be formed by repeating: (1) pulsing one or more silicon-containing precursors for a predetermined time, followed by (2) purging excess precursors. The amorphous silicon initiation layer may not include long-range order, instead, the amorphous silicon layer may have a continuous random network of silicon atoms.

As described earlier, the amorphous silicon initiation layer may be highly conformal. Without being limited by any theory, silicon-containing precursors having low sticking coefficients may be capable of producing highly conformal amorphous silicon layers. In some cases, the sticking coefficient of the precursors (at the relevant deposition conditions) may be about 0.05 or less, for example about 0.001 or less.

In some embodiments, silicon-containing precursors may include at least one or more Si—Si bonds and/or one or more Si—H bonds. Silicon-containing precursors suitable for use in accordance with disclosed embodiments may include polysilanes (H₃Si—(SiH₂)ₙ—SiH₃), where n≥0. Examples of silanes are silane (SiH₄), disilane (Si₂H₆), trisilane (Si₃H₈), and organosilanes such as methylsilane, ethylsilane, isopropylsilane, t-butylsilane, dimethylsilane, diethylsilane, di-t-butylsilane, allylsilane, sec-butylsilane, thexylsilane, isoamylsilane, t-butyldisilane, di-t-butyldisilane, and the like. In some embodiments, the one or more silicon-containing precursors include silane, disilane, or trisilane.

In some embodiments, silicon-containing precursors may also include a halosilane. A halosilane includes at least one halogen group and may or may not include hydrogens and/or carbon groups. Examples of halosilanes are iodosilanes, bromosilanes, chlorosilanes, and fluorosilanes. Specific chlorosilanes are tetrachlorosilane, trichlorosilane, dichlorosilane, monochlorosilane, chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, t-butyldimethylchlorosilane, thexyldimethylchlorosilane, and the like.

In some embodiments, silicon-containing precursors may also include an aminosilane. An aminosilane includes at least one nitrogen atom bonded to a silicon atom, but may also contain hydrogens, oxygens, halogens, and carbons. Examples of aminosilanes are mono-, di-, tri- and tetra-aminosilane (H₃Si(NH₂), H₂Si(NH₂)₂, HSi(NH₂)₃ and Si(NH₂)₄, respectively), as well as substituted mono-, di-, tri- and tetra-aminosilanes, for example, t-butylaminosilane, methylaminosilane, tert-butylsilanamine, bis(tert-butylamino)silane (SiH₂(NHC(CH₃)₃)₂ (BTBAS), tert-butyl silylcarbamate, SiH(CH₃)—(N(CH₃)₂)₂, SiHCl—(N(CH₃)₂)₂, (Si(CH₃)₂NH)₃, diisopropylamino silane, di-sec-butyl amino silane, and the like. A further example of an aminosilane is trisilylamin (N(SiH₃)). In some embodiments, an aminosilane that has two or more amine groups attached to the central Si atom may be used. These may result in less damage than aminosilanes having only a single amine group attached.

Further examples of silicon-containing precursors include trimethylsilane (3MS); ethylsilane; butasilanes; pentasilanes; octasilanes; heptasilane; hexasilane; cyclobutasilane; 1-dimethylamino-1,1,5,5,5-pentamethyl disiloxane; cycloheptasilane; cyclohexasilane; cyclooctasilane; cyclopentasilane; 1,4-dioxa-2,3,5,6-tetrasilacyclohexane; diethoxymethylsilane (DEMS); diethoxysilane (DES); dimethoxymethylsilane; dimethoxysilane (DMOS); methyl-diethoxysilane (MDES); methyl-dimethoxysilane (MDMS); octamethoxy dodecasiloxane (OMODDS); tert-butoxy disilane; tetramethylcyclotetrasiloxane (TMCTS); tetraoxymethylcyclotetrasiloxane (TOMCTS); triethoxysilane (TES); triethoxysiloxane (TRIES); and trimethoxysilane (TMS or TriMOS).

In addition to the precursor gas, an inert carrier gas or diluent gas can be flowed to the semiconductor substrate. Examples of an inert carrier gas or diluent gas include but not limited to helium (He), neon (Ne), argon (Ar), krypton (Kr), xenon (Xe), and nitrogen (N2). In some embodiments, a gas mixture of one or more source gases and one or more of the inert carrier gas or diluent gas may be provided.

By way of an example, one or more silicon-containing precursors include silane, disilane, trisilane, or other silane-based precursor. The silane-based precursor may be flowed into the process chamber and adsorbed on exposed surfaces of the semiconductor substrate. The silane-based precursor may thermally decompose to form the amorphous silicon initiation layer under certain CVD operating conditions (e.g., 400° C.-650° C., 0.1-30 Torr). Thermal decomposition breaks down the silane-based precursor into atoms and/or molecules for deposition on the surface of the semiconductor substrate at elevated temperatures. Plasma-based deposition processes may lead to non-conformal deposition of amorphous silicon, but thermal decomposition of silane-based precursors at sufficiently high temperatures provides highly conformal deposition of amorphous silicon.

The amorphous silicon initiation layer deposits conformally on exposed surfaces of the one or more semiconductor device structures, including exposed surfaces of the electrically conductive layer and the dielectric capping layer. This may include sidewalls of the electrically conductive layer, sidewalls of the dielectric capping layer, and a top surface of the dielectric capping layer. This may further include sidewalls of the semiconductor layer. The amorphous silicon initiation layer may deposit on both horizontal and vertical surfaces of the one or more semiconductor device structures. It should be noted that the term “vertical” as used herein includes near 90° from planar as well as perfectly vertical surfaces. For example, a vertical surface may be +/−10° or +/−5° or +/−1° or +/−0.5° from 90°. Similarly, horizontal surfaces may vary from +/−5° or +/−1° or +/−0.5° from 180°.

In some embodiments, an amorphous boron initiation layer may be formed as an alternative to an amorphous silicon initiation layer. Like an amorphous silicon initiation layer, the amorphous boron initiation layer may be highly conformal. The amorphous boron initiation layer can have a thickness equal to or less than about 100 Å, equal to or less than about 50 Å, or between about 2 Å and about 30 Å. The amorphous boron initiation layer may be deposited using a suitable deposition process such as thermal CVD. As used herein, thermal CVD may refer to a non-plasma vapor deposition process, where deposition of reactants are driven at least in part by thermal energy. In some cases, the amorphous boron initiation layer is deposited using a boron-containing precursor such as borane (BH₃), diborane (B₂H₆), or triborane (B₃H₇). Other examples of boron-containing precursors include higher order boranes such as tetraborane (B₄H₁₀), pentaborane (B₅H₉), hexaborane (B₆H₁₀), and decaborane (B₁₀H₁₄). In some embodiments, the boron-containing precursor includes a borazine having a chemical formula BₓH_{y}N_{z}.

At block 530 of the process 500, a spacer layer is deposited on the amorphous silicon initiation layer. It will be understood that in some alternative embodiments of the process 500, the spacer layer is deposited on the amorphous boron initiation layer. The spacer layer may be a dielectric material such as a low-k dielectric material. As used herein, a “low-k dielectric material” may have a dielectric constant equal to or less than about 5.0 or equal to or less than about 4.0. In some embodiments, the spacer layer includes a silicon-containing layer such as silicon oxide, silicon nitride, silicon carbide, silicon oxycarbide, silicon oxynitride, silicon carbonitride, or silicon oxycarbonitride. For example, the spacer layer includes silicon oxycarbide. In some other embodiments, the spacer layer includes a boron-containing layer such as boron carbide, boron nitride, boron oxide, boron oxynitride, boron oxycarbide, boron carbonitride, or boron oxycarbonitride. Where the one or more semiconductor device structures include a plurality of semiconductor device structures spaced apart by recessed features, the spacer layer may separate/isolate the semiconductor device structures from one another. In some aspects, the spacer layer may serve to electrically isolate adjacent bitlines in a memory array.

The spacer layer may be deposited over at least the dielectric capping layer and the electrically conductive layer, with the amorphous silicon initiation layer positioned between the spacer layer and the dielectric capping layer and positioned between the spacer layer and the electrically conductive layer. The spacer layer may be deposited uniformly or at least substantially uniformly over the dielectric capping layer and the electrically conductive layer. As used herein, deposited “substantially uniformly” over the dielectric capping layer and the electrically conductive layer refers to an average thickness of the spacer layer over the dielectric capping layer being within +/−10% of an average thickness of the spacer layer over the electrically conductive layer. This shows that an amount of spacer material deposited over the electrically conductive layer is about the same as an amount of spacer material deposited over the dielectric capping layer. In some embodiments, the spacer layer is deposited uniformly or at least substantially uniformly over the dielectric capping layer, the electrically conductive layer, and the semiconductor layer of the one or more semiconductor device structures.

The amorphous silicon initiation layer promotes nucleation and growth of the spacer layer over at least the dielectric capping layer and the electrically conductive layer of the one or more semiconductor device structures. Whereas growth of a spacer layer may be inhibited or slowed on an electrically conductive layer (e.g., tungsten) relative to a dielectric capping layer, amorphous silicon promotes consistent growth of the spacer layer on both the electrically conductive layer and the dielectric capping layer. Thus, the amorphous silicon initiation layer mitigates nucleation delay in the electrically conductive layer. Furthermore, the amorphous silicon initiation layer does not adversely impact the electrical performance of the electrically conductive layer. In some cases, an electrical resistance of the electrically conductive layer is preserved or even improved with the amorphous silicon initiation layer.

Deposition of the spacer layer and the amorphous silicon initiation layer may occur in the same process chamber. This avoids unwanted vacuum breaks between substrate transfers, which may expose the semiconductor substrate to unwanted materials or particles. This also reduces processing time, reduces processing steps, reduces costs, and increases throughput. The process chamber may be configured for CVD-based deposition processes including deposition of the amorphous silicon initiation layer and the spacer layer. For instance, amorphous silicon initiation layer may be deposited by thermal CVD in the process chamber and the spacer layer may be deposited by remote plasma CVD in the same process chamber.

In depositing amorphous silicon by thermal CVD, the one or more semiconductor device structures may be exposed to a silane-based precursor in the process chamber, and thermal energy is applied to thermally decompose the silane-based precursor to deposit the amorphous silicon initiation layer in the process chamber. The process chamber may be equipped to supply the silane-based precursor and apply thermal energy using one or more heating elements for controlling a temperature of the semiconductor substrate. The one or more heating elements may apply thermal energy by heating the semiconductor substrate to a temperature between about 400° C. and about 650° C. In depositing the spacer layer (e.g., silicon oxycarbide) by remote plasma CVD, the one or more semiconductor device structures may be exposed to a silicon-containing precursor in the process chamber, radicals of a source gas (e.g., hydrogen source gas) are generated in a remote plasma source located upstream of the process chamber, and the radicals of the source gas are introduced into the process chamber and towards the semiconductor substrate to react with the silicon-containing precursor to form the spacer layer. In some embodiments, the radicals of the source gas include radicals of hydrogen. The radicals of hydrogen may interact with the silicon-containing precursor at a location downstream from the remote plasma source to activate the silicon-containing precursor in an environment adjacent to the semiconductor substrate, thereby depositing the spacer layer.

The silicon-containing precursor may include one or more Si—H bonds and/or one or more Si—Si bonds. In some embodiments, the silicon-containing precursors further include one or more Si—O bonds, one or more Si—N bonds, and/or one or more Si—C bonds. For depositing silicon oxycarbide, the silicon-containing precursors may include one or both of Si—O and Si—C bonds. In some embodiments, the silicon-containing precursor can be a siloxane. In some embodiments, the siloxane may be cyclic. Cyclic siloxanes may include cyclotetrasiloxanes, such as 2,4,6,8-tetramethylcyclotetrasiloxane (TMCTS), octamethylcyclotetrasiloxane (OMCTS), and heptamethylcyclotetrasiloxane (HMCTS). Other cyclic siloxanes can also include but are not limited to cyclotrisiloxanes and cyclopentasiloxanes. In some embodiments, the siloxane may be linear. Examples of suitable linear siloxanes include but are not limited to disiloxanes, such as pentamethyldisiloxane (PMDSO) and tetramethyldisiloxane (TMDSO), and trisiloxanes such as hexamethyltrisiloxane, heptamethyltrisiloxane. In some embodiments, the silicon-containing precursor can be an alkoxy silane. Alkoxy silanes include a central silicon atom with one or more alkoxy groups bonded it and one or more hydrogen atoms bonded to it. Examples include but are not limited to trimethoxysilane (TMOS), dimethoxysilane (DMOS), methoxysilane (MOS), methyldimethoxysilane (MDMOS), diethyoxymethylsilane (DEMS), dimethylethoxysilane (DMES), and dimethylmethoxy silane (DMMOS).

During the deposition process by remote plasma CVD, the radicals of hydrogen or other source gas may selectively break Si—H bonds and/or Si—Si bonds, but preserve or substantially preserve Si—O bonds (if any), Si—N bonds (if any), and Si—C bonds (if any). The broken bonds may serve as sites for cross-linking during or after deposition. Bonding at the reactive sites and cross-linking can form a primary backbone or matrix collectively in the resulting spacer layer.

The radicals of hydrogen or other source gas may be in a low energy state or ground state in the environment adjacent to the semiconductor substrate. This provides mild reaction conditions when reacting with the silicon-containing precursors. The radicals may include hydrogen radicals (i.e., hydrogen atom radicals). In some embodiments, all, or substantially all, or a substantial fraction of the hydrogen atom radicals can be in the ground state, e.g., at least about 90% or 95% of the hydrogen atom radicals adjacent the semiconductor substrate are in the ground state. In certain embodiments, source gas is provided in a carrier gas such as helium. As an example, hydrogen gas may be provided in a helium carrier at a concentration of about 1-10% hydrogen.

Once generated in the remote plasma source, the radicals of the source gas may be in an excited energy state. For example, hydrogen in an excited energy state can have an energy of at least 10.2 eV (first excited state). Excited hydrogen atom radicals may cause unselective decomposition of a silicon-containing precursor. For example, hydrogen atom radicals in an excited state can easily break Si—H, Si—Si, Si—N, Si—O, and Si—C bonds, which can alter the composition or physical or electrical characteristics of the spacer layer. In some embodiments, when the excited hydrogen atom radicals lose their energy, or relax, the excited hydrogen atom radical may become a low energy state hydrogen atom radical or a ground state hydrogen atom radical. Hydrogen atom radicals in a low energy state or ground state can be capable of selectively breaking Si—H and Si—Si bonds while generally preserving Si—O, Si—N, and Si—C bonds.

In some embodiments, the silicon-containing precursor may be provided with a co-reactant. Example co-reactants include carbon dioxide (CO₂), carbon monoxide (CO), water (H₂O), methanol (CH₃OH), oxygen (O₂), ozone (O₃), nitrogen (N₂), nitrous oxide (N₂O), ammonia (NH₃), diazene (N₂H₂), methane (CH₄), ethane (C₂H₆), acetylene (C₂H₂), ethylene (C₂H₄), diborane (B₂H₆), and combinations thereof. The co-reactant may be provided into the process chamber along the same flow path as the silicon-containing precursor. Alternatively, the co-reactant may be provided along a separate flow path of the silicon-containing precursor. The radicals of the source gas may react with both the silicon-containing precursor and the co-reactant in the environment adjacent to the semiconductor substrate to form the spacer layer.

In some embodiments of the process 500, the amorphous silicon initiation layer is exposed to plasma to convert the amorphous silicon initiation layer to a doped silicon layer prior to depositing the spacer layer. The doped silicon layer may include silicon carbide, silicon oxycarbide, silicon carbonitride, or silicon oxycarbonitride. The plasma may include radicals of one or more of carbon, oxygen, hydrogen, or nitrogen. In some embodiments, the plasma may include radicals of a dopant gas, where the dopant gas includes one or more of the following: nitrogen (N₂), ammonia (NH₃), diazene (N₂H₂), or hydrazine (N₂H₄), acetylene (C₂H₂), ethylene (C₂H₄), propene (C₃H₆), hydrogen (H₂), methane (CH₄), oxygen (O₂), water (H₂O), carbon monoxide (CO), carbon dioxide (CO₂), nitrous oxide (N₂O), or nitrogen dioxide (NO₂). The radicals of the dopant gas may include hydrogen radicals (H^{*}), nitrogen radicals (N^{*}), oxygen radicals (O^{*}), carbon radicals (C^{*}), amine radicals (NH^{*}, NH₂^{*}), or combinations thereof. In some embodiments, conversion of amorphous silicon initiation layer may occur in the same process chamber as deposition of the amorphous silicon initiation layer and deposition of the spacer layer. That way, deposition and conversion steps can occur without introducing a vacuum break in between operations. The plasma used in conversion may be a remote plasma, where the radicals of the dopant gas are generated in a remote plasma source. The remote plasma is introduced from the remote plasma source through a showerhead into the process chamber, where the amorphous silicon initiation layer is exposed to the remote plasma to form the doped silicon layer. Composition of the dopant gas, relative flow rates, pressure, conversion time, plasma power, plasma frequency, and other parameters may be controlled to tune a composition of the doped silicon layer. The doped silicon layer may serve as an initiation layer for subsequent deposition of the spacer layer, which is discussed below in a process flow in FIG. 6.

In some embodiments of the process 500 where the amorphous silicon initiation layer is replaced by an amorphous boron initiation layer, the amorphous boron initiation layer is exposed to plasma to convert the amorphous boron initiation layer to a doped boron layer prior to depositing the spacer layer. The doped boron layer may include boron carbide, boron nitride, boron oxide, boron oxynitride, boron oxycarbide, boron carbonitride, or boron oxycarbonitride. The plasma may include radicals of one or more of carbon, oxygen, hydrogen, or nitrogen. In some embodiments, the plasma may include radicals of a dopant gas, where the dopant gas includes one or more of the following: nitrogen (N₂), ammonia (NH₃), diazene (N₂H₂), or hydrazine (N₂H₄), acetylene (C₂H₂), ethylene (C₂H₄), propene (C₃H₆), hydrogen (H₂), methane (CH₄), oxygen (O₂), water (H₂O), carbon monoxide (CO), carbon dioxide (CO₂), nitrous oxide (N₂O), or nitrogen dioxide (NO₂). The radicals of the dopant gas may include hydrogen radicals (H^{*}), nitrogen radicals (N^{*}), oxygen radicals (O^{*}), carbon radicals (C^{*}), amine radicals (NH^{*}, NH₂^{*}), or combinations thereof. In some embodiments, conversion of amorphous boron initiation layer may occur in the same process chamber as deposition of the amorphous boron initiation layer and deposition of the spacer layer. That way, deposition and conversion steps can occur without introducing a vacuum break in between operations. The plasma used in conversion may be a remote plasma, where the radicals of the dopant gas are generated in a remote plasma source. The remote plasma is introduced from the remote plasma source through a showerhead into the process chamber, where the amorphous boron initiation layer is exposed to the remote plasma to form the doped boron layer. Composition of the dopant gas, relative flow rates, pressure, conversion time, plasma power, plasma frequency, and other parameters may be controlled to tune a composition of the doped boron layer. The doped boron layer may serve as an initiation layer for subsequent deposition of the spacer layer.

FIG. 6 illustrates a flow chart of an example method of forming a spacer layer on one or more semiconductor device structures according to some other embodiments. The operations of a process 600 may be performed in different orders and/or with different, fewer, or additional operations. One or more operations of the process 600 may be performed using a substrate processing apparatus shown in FIG. 9 or 10. In some embodiments, the operations of the process 600 may be implemented, at least in part, according to software stored in one or more non-transitory computer readable media.

At block 610 of the process 600, a semiconductor substrate is provided having one or more semiconductor device structures, where each of the semiconductor device structures comprises at least a dielectric capping layer over an electrically conductive layer. The semiconductor substrate is provided in a process chamber. The process chamber configured to receive the semiconductor substrate is also configured to deposit an initiation layer. In some embodiments, the process chamber used for depositing the initiation layer is the same for depositing a spacer layer. Aspects of the block 610 of the process 600 may be identical or similar to block 510 of the process 500. Accordingly, details regarding the semiconductor substrate, the process chamber, and the one or more semiconductor device structures in block 610 of the process 600 can be found in the description at block 510 of the process 500.

At block 620 of the process 600, a silicon-based initiation layer is conformally deposited on the dielectric capping layer and electrically conductive layer of the one or more semiconductor device structures. The silicon-based initiation layer may be deposited using a two-step process, where an amorphous silicon layer is conformally deposited on exposed surfaces of the one or more semiconductor device structures, and the amorphous silicon layer is subsequently converted to a doped silicon layer by exposure to plasma. The doped silicon layer forms the silicon-based initiation layer. In some embodiments, the silicon-based initiation layer may have a thickness equal to or less than about 100 Å, equal to or less than about 50 Å, or between about 2 Å and about 30 Å. The silicon-based initiation layer may be a thin or ultrathin layer of doped silicon deposited conformally on at least two different material surfaces and serves as a single material surface on which a subsequent layer (e.g., spacer layer) is deposited thereon.

In some embodiments, the silicon-based initiation layer includes silicon oxide, silicon nitride, silicon carbide, silicon oxycarbide, silicon oxynitride, silicon carbonitride, or silicon oxycarbonitride. For example, the silicon-based initiation layer includes silicon carbide, silicon oxycarbide, silicon carbonitride, or silicon oxycarbonitride. These silicon-based initiation layers may promote nucleation of a subsequent layer (e.g., spacer layer) while avoiding nucleation delay over the electrically conductive layer. Moreover, some of these silicon-based initiation layers do not adversely impact the electrical performance of the electrically conductive layer.

Formation of the silicon-based initiation layer may proceed by deposition of an amorphous silicon layer followed by conversion of the amorphous silicon layer upon exposure to plasma flow. Examples of techniques for forming an amorphous silicon layer may include PVD, thermal CVD, LPCVD, PECVD, hot-wire CVD, ALD, and PEALD. In some embodiments, the amorphous silicon layer may be formed by thermal CVD via a thermal decomposition process. The thermal decomposition process is initiated by activation of precursor gas species at elevated temperatures, where the precursor gas species breaks down thermally into atoms and/or molecules for deposition by CVD.

In some embodiments, the thickness of the amorphous silicon layer can be controlled according to a predetermined deposition time to achieve a desired thickness. In some embodiments, the deposition time can be between about 5 seconds and about 500 seconds, or between about 10 seconds and about 200 seconds. In some embodiments, a desired thickness of the amorphous silicon layer can be between about 1 Å and about 1000 Å, between about 2 Å and about 50 Å, or between about 2 Å and about 30 Å. The deposition time can correspond to the desired thickness of the amorphous silicon layer. The thickness may be controlled to enable sufficient penetration of radicals and/or ions in the amorphous silicon layer from a subsequent plasma treatment.

For some embodiments, deposition of the amorphous silicon layer can occur by flowing one or more silicon-containing precursors into the process chamber towards the semiconductor substrate. The silicon-containing precursors are transported to the substrate surface where they are adsorbed by the semiconductor substrate to form a highly conformal amorphous silicon layer. In some embodiments, forming an amorphous silicon layer by CVD may necessitate controlling the deposition pressure ranging from 0.1 Torr to 30 Torr or from 0.5 Torr and about 10 Torr. Substrate temperature during amorphous silicon deposition may be controlled to be between about 300° C. and about 700° C., between about 400° C. and about 650° C., or between about 450° C. and about 600° C. After deposition, a step coverage for the amorphous silicon layer may be at least about 85%. In some embodiments, a step coverage may be at least about 90%, at least about 95%, or at least about 98%.

The silicon-containing precursors may have low sticking coefficients as described earlier. In some cases, the sticking coefficient of the silicon-containing precursors may be about 0.05 or less, for example about 0.001 or less. In some embodiments, the silicon-containing precursors may include at least one or more Si—Si bonds and/or one or more Si—H bonds, where the silicon-containing precursors may be silane-based precursors as described earlier. By way of an example, the silicon-containing precursors include silane, disilane, trisilane, or other silane-based precursor.

The amorphous silicon layer deposits conformally on exposed surfaces of the one or more semiconductor device structures, including exposed surfaces of the electrically conductive layer and the dielectric capping layer. This may include sidewalls of the electrically conductive layer, sidewalls of the dielectric capping layer, and a top surface of the dielectric capping layer. This may further include sidewalls of the semiconductor layer. The amorphous silicon layer may deposit on both horizontal and vertical surfaces of the one or more semiconductor device structures.

The amorphous silicon layer is exposed to plasma to convert the amorphous silicon layer to a doped silicon layer. The plasma may include radical species and/or ions generated in a plasma source. In some embodiments, the plasma source may be an in situ plasma source. In some embodiments, the plasma source may be a remote plasma source, where the remote plasma source is separate from the process chamber. A remote plasma may be generated in the remote plasma source and introduced into the process chamber through a showerhead to flow towards a surface of the semiconductor substrate.

A source gas (e.g., hydrogen source gas) may be provided to the plasma source. Radicals and/or ions of the source gas may form the plasma generated in the plasma source. In some embodiments, the plasma may include radicals of nitrogen, oxygen, hydrogen, or carbon. One or more of the aforementioned radicals may act as dopants to form the doped silicon layer. The source gas may include gas species comprising nitrogen-containing reactants including nitrogen, ammonia, diazene, or hydrazine; hydrogen-containing reactants including hydrogen or methane; hydrocarbons including acetylene, ethylene, or propene; oxygen or oxide reactants including oxygen, water, carbon monoxide, carbon dioxide, nitrous oxide, or nitrogen dioxide, or mixtures thereof. The gas species may be determined based on one or more doping elements required for forming the doped silicon layer. For example, nitrogen-containing reactants may be delivered to form a silicon nitride layer. In another example, carbon-containing reactants may be delivered to form a silicon carbide layer. In yet another example, carbon- and nitrogen-containing reactants may be delivered to the amorphous silicon layer to form a silicon carbonitride layer. In still yet another example, oxygen- and carbon-containing reactants may be delivered to the amorphous silicon layer to form a silicon oxycarbide layer. In some embodiments, a composition of one or more source gases in the plasma (e.g., remote plasma) may be controlled to tune a composition of the doped silicon layer.

The pressure in the process chamber may be adjusted to increase ionization of the one or more gas species in the source gas and reduce residence times of the radicals. Reduced residence times may reduce the effect of recombination of the radicals. A lower pressure allows molecules to move faster, which results in increased ionization of the source gas, reduced residence times, and reduced recombination of radicals. In some embodiments, the pressure can be between about 0.2 Torr and about 10 Torr or between about 1 Torr and about 3 Torr. However, it will be understood that the pressure in the process chamber during the exposure to plasma can be greater than 3 Torr or greater than 10 Torr, where other process conditions (e.g., inert carrier gas) cause sufficient ionization and reduced residence times.

The amorphous silicon layer may be exposed to the plasma for a predetermined time. In some embodiments, the predetermined time can be between about 2 seconds and about 100 seconds or between about 5 seconds and about 50 seconds. Determination of the treatment time may depend on the thickness of the amorphous silicon layer, where thicker layers may require longer time to be exposed to the plasma.

In addition to time and pressure during the exposure to the plasma for conversion, one or more process conditions may be controlled by tuning one or more of RF power, source gas flow, source gas composition, and other process conditions to influence the characteristics of the plasma, which can thereby result in different bond density in the amorphous silicon layer prior to or during the conversion.

Deposition and conversion of the amorphous silicon layer may be achieved with one cycle of deposition and conversion. Alternatively, deposition and conversion of the amorphous silicon layer can be achieved with alternating deposition and conversion cycles. Deposition and conversion may occur in a layer-by-layer approach to allow for each plasma conversion cycle to fully convert the deposited amorphous silicon layer such that substantially the entirety of the deposited amorphous silicon layer is doped. That way, the entire amorphous silicon stack can be uniformly converted to a doped silicon layer, and have a more uniform distribution of dopant species across a thickness of a doped silicon layer. Therefore, it will be understood that deposition and conversion cycles in the formation of the doped silicon layer may continue to repeat until a desired thickness of the doped silicon layer is achieved.

Just as the amorphous silicon layer is conformally deposited, conversion of the amorphous silicon layer into the doped silicon layer to form the silicon-based initiation layer may result in a highly conformal initiation layer on the one or more semiconductor device structures. In some embodiments, the silicon-based initiation layer may have a step coverage of at least about 85%, at least about 90%, at least about 95%, or at least about 98% on the one or more semiconductor device structures. As such, the silicon-based initiation layer may be deposited substantially uniformly over the dielectric capping layer and the electrically conductive layer of the one or more semiconductor device structures.

During the conversion from the amorphous silicon layer to the doped silicon layer, the temperature in the environment adjacent to the semiconductor substrate can be any suitable temperature facilitating the conversion reaction by doping one or more gas species into the amorphous silicon layer, but sometimes limited by the application of the device containing the doped silicon layer. In some embodiments, the temperature in the environment adjacent to the substrate can be largely controlled by the temperature of a pedestal on which the semiconductor substrate is supported during plasma treatment/conversion. In some embodiments, the operating temperature can be between about 50° C. and about 650° C. For example, the operating temperature can be between about 250° C. and about 400° C. in many integrated circuit applications. In some embodiments, increasing the temperature may lead to increased number of bonds between silicon atoms and dopant atoms while reducing a number of Si—Si bonds. Increasing the temperature may also lead to increased crystallinity of the doped silicon layer.

In some embodiments, conversion of amorphous silicon layer takes place in the same process chamber as deposition of the amorphous silicon layer. That way, deposition and conversion steps can occur without introducing a vacuum break in between operations.

The conversion of the amorphous silicon layer to the doped silicon layer to form the silicon-based initiation layer may have several advantages. The resulting silicon-based initiation layer may form a conformal layer that is desirable for manufacturing high aspect ratio features in a semiconductor device, where the conformal layer provides uniform deposition even on surfaces of two or more materials. Treatment of amorphous silicon and deposition of amorphous silicon may occur in the same process chamber to avoid contamination and increase throughput. Compositional tunability in the silicon-based initiation layer with one or more dopants is also possible. Further, forming the silicon-based initiation layer according to some embodiments of the present disclosure can have a throughput faster than conventional ALD processes.

In some embodiments, the process 900 involves conformal deposition of a boron-based initiation layer on the dielectric capping layer and electrically conductive layer of the one or more semiconductor device structures instead of a silicon-based initiation layer. An amorphous boron layer is conformally deposited on exposed surfaces of the one or more semiconductor device structures, and the amorphous boron layer is subsequently converted to a doped boron layer by exposure to plasma. The doped boron layer forms the boron-based initiation layer. In some embodiments, the boron-based initiation layer may have a thickness equal to or less than about 100 Å, equal to or less than about 50 Å, or between about 2 Å and about 30 Å. Deposition of the amorphous boron layer occurs using a boron-containing precursor such as borane (BH₃), diborane (B₂H₆), or triborane (B₃H₇). The amorphous boron layer may be exposed to plasma to convert the amorphous boron layer to a doped boron layer. The doped boron layer may include boron carbide, boron nitride, boron oxide, boron oxynitride, boron oxycarbide, boron carbonitride, or boron oxycarbonitride. The plasma may include radicals of one or more of carbon, oxygen, hydrogen, or nitrogen. In some instances, the plasma is a remote plasma. In some embodiments, conversion of amorphous boron layer may occur in the same process chamber as deposition of the amorphous boron layer and deposition of the spacer layer.

At block 630 of the process 600, a spacer layer is deposited on the silicon-based initiation layer. It will be understood that in some alternative embodiments of the process 300, a spacer layer is deposited on the boron-based initiation layer. The spacer layer may be a dielectric material such as a low-k dielectric material. In some embodiments, the spacer layer includes a silicon-containing layer such as silicon oxide, silicon nitride, silicon carbide, silicon oxycarbide, silicon oxynitride, silicon carbonitride, or silicon oxycarbonitride. For example, the spacer layer includes silicon oxycarbide. Where the one or more semiconductor device structures include a plurality of semiconductor device structures spaced apart by recessed features, the spacer layer may separate/isolate the semiconductor device structures from one another. In some aspects, the spacer layer may serve to electrically isolate adjacent bitlines in a memory array. In some embodiments, the one or more semiconductor device structures are DRAM bit structures that are part of a DRAM array, where the DRAM bit structures may be vertically-oriented structures having at least a bitline. The DRAM bit structures may be spaced apart by recessed features such as trenches, where the recessed features may have a depth to width aspect ratio equal to or greater than about 10:1, equal to or greater than about 20:1, or equal to or greater than about 50:1.

The spacer layer may be deposited over at least the dielectric capping layer and the electrically conductive layer, with the amorphous silicon initiation layer positioned between the spacer layer and the dielectric capping layer and positioned between the spacer layer and the electrically conductive layer. The spacer layer may be deposited uniformly or at least substantially uniformly over the dielectric capping layer and the electrically conductive layer. In some embodiments, the spacer layer is deposited uniformly or at least substantially uniformly over the dielectric capping layer, the electrically conductive layer, and the semiconductor layer of the one or more semiconductor device structures. In some embodiments, the dielectric capping layer comprises silicon nitride, the electrically conductive layer comprises tungsten or molybdenum, and the semiconductor layer comprises polysilicon. The electrically conductive layer may serve as one or more bitlines in the DRAM array.

The silicon-based initiation layer promotes nucleation and growth of the spacer layer over at least the dielectric capping layer and the electrically conductive layer of the one or more semiconductor device structures. Whereas growth of a spacer layer may be inhibited or slowed on an electrically conductive layer (e.g., tungsten) relative to a dielectric capping layer, a doped silicon layer such as silicon carbide, silicon oxycarbide, silicon carbonitride, or silicon oxycarbonitride promotes consistent growth of the spacer layer on both the electrically conductive layer and the dielectric capping layer. Hence, the silicon-based silicon initiation layer mitigates nucleation delay in the electrically conductive layer. Furthermore, the silicon-based initiation layer does not adversely impact the electrical performance of the electrically conductive layer. In some cases, an electrical resistance of the electrically conductive layer is preserved or even improved with the silicon-based initiation layer.

Deposition of the spacer layer and the silicon-based initiation layer may occur in the same process chamber. This avoids unwanted vacuum breaks between substrate transfers, which may expose the semiconductor substrate to unwanted materials or particles. This also reduces processing time, reduces processing steps, reduces costs, and increases throughput. The process chamber may be configured for CVD-based deposition of the amorphous silicon layer, for treatment/conversion of the amorphous silicon layer to the silicon-based initiation layer by exposure to plasma, and for CVD-based deposition of the spacer layer. For instance, amorphous silicon layer may be deposited by thermal CVD in the process chamber, the amorphous silicon layer may be treated/converted using a remote plasma to form the silicon-based initiation layer, and the spacer layer may be deposited by remote plasma CVD in the same process chamber.

In depositing the spacer layer (e.g., silicon oxycarbide) by remote plasma CVD, the one or more semiconductor device structures may be exposed to a silicon-containing precursor in the process chamber, radicals of a source gas (e.g., hydrogen source gas) are generated in a remote plasma source located upstream of the process chamber, and the radicals of the source gas are introduced into the process chamber and towards the semiconductor substrate to react with the silicon-containing precursor to form the spacer layer. In some embodiments, the radicals of the source gas include radicals of hydrogen. The radicals of hydrogen may interact with the silicon-containing precursor at a location downstream from the remote plasma source to activate the silicon-containing precursor in an environment adjacent to the semiconductor substrate. The remote plasma source used for generation of radicals for depositing the spacer layer may be the same remote plasma source used for generation of radicals for conversion of the amorphous silicon layer. Deposition of the amorphous silicon layer, conversion of the amorphous silicon layer, and deposition of the spacer layer may take place in the same process chamber having the same remote plasma source located upstream of the process chamber.

The silicon-containing precursor may include one or more Si—H bonds and/or one or more Si—Si bonds. In some embodiments, the silicon-containing precursors further include one or more Si—O bonds, one or more Si—N bonds, and/or one or more Si—C bonds. For depositing silicon oxycarbide, the silicon-containing precursors may include one or both of Si—O and Si—C bonds. In some embodiments, the silicon-containing precursor can be a siloxane. In some embodiments, the silicon-containing precursor can be an alkoxy silane. Aspects of the silicon-containing precursor used to deposit the spacer layer are described above.

During deposition by remote plasma CVD, the radicals of hydrogen or other source gas may selectively break Si—H bonds and/or Si—Si bonds but preserve Si—O bonds (if any), Si—N bonds (if any), and Si—C bonds (if any). The broken bonds may serve as sites for cross-linking during or after deposition. Bonding at the reactive sites and cross-linking can form a primary backbone or matrix collectively in the resulting spacer layer.

The radicals may be in a low energy state or ground state in the environment adjacent to the semiconductor substrate. This provides mild reaction conditions when reacting with the silicon-containing precursors. The radicals may include hydrogen radicals (i.e., hydrogen atom radicals). In some embodiments, all, or substantially all, or a substantial fraction of the hydrogen atom radicals can be in the ground state, e.g., at least about 90% or 95% of the hydrogen atom radicals adjacent the semiconductor substrate are in the ground state. In certain embodiments, source gas is provided in a carrier gas such as helium. As an example, hydrogen gas may be provided in a helium carrier at a concentration of about 1-10% hydrogen.

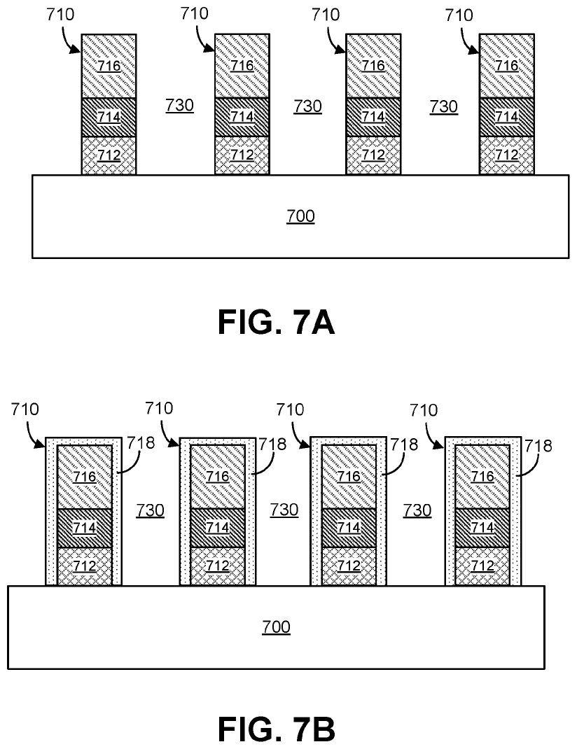

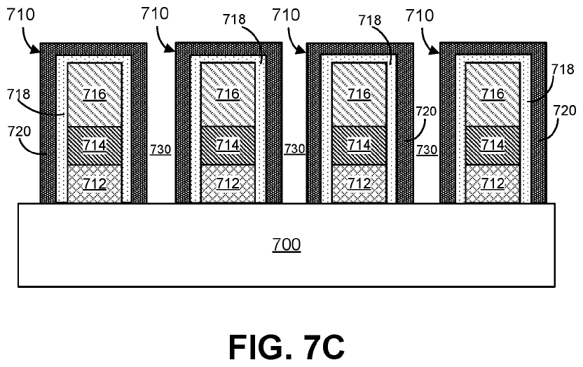

FIGS. 7A-7C show cross-sectional schematic illustrations of an example semiconductor substrate undergoing formation of spacers on a plurality of semiconductor device structures according to some embodiments. FIG. 7A shows a semiconductor substrate 700 with a plurality of semiconductor device structures 710. In some embodiments, the plurality of semiconductor device structures 710 are memory device structures of a memory array. For example, the memory device structures may comprise bit structures in a DRAM array, where each of the bit structures may comprise a bitline and a capping layer on the bitline. In some instances, the bitline may be coupled to a polysilicon layer of a transistor. The semiconductor substrate 700 may be provided in a process chamber, where the process chamber is configured to performing CVD-based operations.

The plurality of semiconductor device structures 710 may be separated by recessed features 730 such as trenches. The recessed features 730 may be formed by patterning the semiconductor substrate 700. The recessed features 730 may be high aspect ratio features having a depth to width aspect ratio equal to or greater than about 10:1, equal to or greater than about 20:1, or equal to or greater than about 50:1.

Each of the plurality of semiconductor device structures 710 includes a stack of materials, including at least an electrically conductive layer 714 and a dielectric capping layer 716 over the electrically conductive layer 714. In some embodiments, each of the plurality of semiconductor device structures 710 further includes a semiconductor layer 712, where the electrically conductive layer 714 is over the semiconductor layer. In some embodiments, the electrically conductive layer 714 includes tungsten, tantalum, titanium, molybdenum, hafnium, cobalt, chrome, nickel, platinum, ruthenium, copper, aluminum, or alloys thereof. For example, the electrically conductive layer 714 includes tungsten or molybdenum. The electrically conductive layer 714 may function as bitlines in a DRAM array. In some embodiments, the dielectric capping layer 716 includes an electrically insulating material such as nitride or oxide. For instance, the dielectric capping layer 716 includes silicon nitride. The dielectric capping layer 716 may function as a capping layer on bitlines of a DRAM array. The dielectric capping layer 716 may also serve as a bitline hard mask. In some embodiments, the semiconductor layer 712 includes polysilicon or other suitable semiconductor material.

FIG. 7B shows the semiconductor substrate 700 of FIG. 7A after an initiation layer 718 is deposited on the plurality of semiconductor device structures 710. The initiation layer 718 may be a thin or ultrathin layer of material that is conformally deposited on each of the plurality of semiconductor device structures 710. In some embodiments, the initiation layer 718 may have a thickness equal to or less than about 100 Å, equal to or less than about 50 Å, or between about 2 Å and about 30 Å. The initiation layer 718 may be conformally deposited on exposed surfaces of the plurality of semiconductor device structures 710, including sidewalls and top surfaces of the plurality of semiconductor device structures 710. This includes conformal deposition on a top surface and sidewalls of the dielectric capping layer 716, sidewalls of the electrically conductive layer 714, and sidewalls of the semiconductor layer 712. The step coverage of the initiation layer 718 may be at least about 85%, at least about 90%, at least about 95%, or at least about 98%.

The initiation layer 718 provides a uniform surface over two or more material surfaces (i.e., dielectric capping layer 716, electrically conductive layer 714, and semiconductor layer 712) and is made of a common material. This common material surface enables growth and nucleation of a subsequent spacer material on the semiconductor device structures 710 while minimizing nucleation delay. In some embodiments, the initiation layer 718 is composed of amorphous silicon. In some other embodiments, the initiation layer 718 is composed of a doped silicon layer such as silicon carbide, silicon carbonitride, or silicon oxycarbonitride, where the doped silicon layer is formed by conversion/treatment of amorphous silicon by exposure to plasma (e.g., remote plasma). In some embodiments, the initiation layer 718 is composed of amorphous boron. In some other embodiments, the initiation layer 718 is composed of a doped boron layer such as boron carbide, boron nitride, boron oxide, boron oxynitride, boron oxycarbide, boron carbonitride, or boron oxycarbonitride.

Where the initiation layer 718 is composed of amorphous silicon, the amorphous silicon may be conformally deposited by a thermal CVD process in the process chamber. The plurality of semiconductor device structures 710 of the semiconductor substrate 700 may be exposed to silane-based precursors, where the silane-based precursors adsorb on exposed surfaces of the plurality of semiconductor device structures 710. Thermal energy is applied to the semiconductor substrate 700 to cause the silane-based precursors to thermally decompose and deposit amorphous silicon in a highly conformal manner. Thermal decomposition may occur at temperatures between about 400° C. and about 650° C. Conformal deposition of the initiation layer 718 by thermal CVD provides greater throughput relative to conventional ALD processes. By way of an example, whereas a conventional ALD process may take 3 to 6 minutes to deposit silicon oxide or silicon nitride to mitigate nucleation delay, a thermal CVD process may take 10 to 20 seconds to conformally deposit amorphous silicon to mitigate nucleation delay.

Where the initiation layer 718 is composed of amorphous boron, the amorphous born may be conformally deposited by a thermal CVD process in the process chamber. The plurality of semiconductor device structures 710 of the semiconductor substrate 700 may be exposed to boron-based precursors (e.g., borane), where the boron-based precursors adsorb on exposed surfaces of the plurality of semiconductor device structures 710. Thermal energy is applied to the semiconductor substrate 400 to cause the boron-based precursors to thermally decompose and deposit amorphous boron in a highly conformal manner. Thermal decomposition may occur at temperatures between about 400° C. and about 650° C.

Where the initiation layer 718 is composed of doped silicon, the doped silicon may be formed by conversion/treatment of the amorphous silicon described above. After conformally depositing the amorphous silicon by thermal CVD, the amorphous silicon may be exposed to plasma containing radicals of a nitrogen-containing reactant, an oxygen-containing reactant, a hydrogen-containing reactant, and/or a carbon-containing reactant. A gas plasma flow may include hydrogen radicals (H^{*}), nitrogen radicals (N^{*}), oxygen radicals (O^{*}), carbon radicals (C^{*}), amine radicals (NH^{*}, NH₂^{*}), or combinations thereof. In some embodiments, the plasma may be a remote plasma generated in a remote plasma source located upstream of the process chamber. The process chamber for conversion/treatment of amorphous silicon may be the same process chamber for deposition of amorphous silicon. The radicals of the plasma may serve as dopant species to convert the amorphous silicon to the doped silicon, where the doped silicon serves as the initiation layer 718. After conversion/treatment of the amorphous silicon into doped silicon, the doped silicon may retain high conformality along the plurality of semiconductor device structures 710.

Where the initiation layer 718 is composed of doped boron, the doped boron may be formed by conversion/treatment of the amorphous boron described above. After conformally depositing the amorphous boron by thermal CVD, the amorphous boron may be exposed to plasma containing radicals of a nitrogen-containing reactant, an oxygen-containing reactant, a hydrogen-containing reactant, and/or a carbon-containing reactant. A gas plasma flow may include hydrogen radicals (H^{*}), nitrogen radicals (N^{*}), oxygen radicals (O^{*}), carbon radicals (C^{*}), amine radicals (NH^{*}, NH₂^{*}), or combinations thereof. In some embodiments, the plasma may be a remote plasma generated in a remote plasma source located upstream of the process chamber. The process chamber for conversion/treatment of amorphous boron may be the same process chamber for deposition of amorphous boron. The radicals of the plasma may serve as dopant species to convert the amorphous boron to the doped boron, where the doped boron serves as the initiation layer 718. After conversion/treatment of the amorphous boron into doped boron, the doped boron may retain high conformality along the plurality of semiconductor device structures 710.

FIG. 7C shows the semiconductor substrate 700 of FIG. 7B after a spacer layer 720 is deposited on the initiation layer 718 of the plurality of semiconductor device structures 710. The spacer layer 720 may provide electrical isolation between adjacent semiconductor device structures 710. In some embodiments, the spacer layer 720 may serve as gapfill or at least partial gapfill in the recessed features 730. The spacer layer 720 may be deposited uniformly or substantially uniformly over the plurality of semiconductor device structures 710. In other words, an average thickness of the spacer layer 720 over the electrically conductive layer 714 is the same or approximately the same as an average thickness of the spacer over the dielectric capping layer 716 and/or over semiconductor layer 712. In some embodiments, an average thickness of the spacer layer 720 is equal to or greater than about 1 nm, equal to or greater than about 3 nm, equal to or greater than about 10 nm, or equal to or greater than about 50 nm.

The spacer layer 720 is composed of an electrically insulating material. In some embodiments, the spacer layer 720 is composed of a low-k dielectric material. In some examples, the spacer layer 720 includes a silicon-containing layer such as silicon oxide, silicon nitride, silicon carbide, silicon oxycarbide, silicon oxynitride, silicon carbonitride, or silicon oxycarbonitride. In some other examples, the spacer layer 720 includes a boron-containing layer such as boron carbide, boron nitride, boron oxide, boron oxynitride, boron oxycarbide, boron carbonitride, or boron oxycarbonitride. In some embodiments, the spacer layer 720 includes silicon oxycarbide.

The spacer layer 720 may be deposited using a CVD-based process in the process chamber. In some embodiments, the process chamber for depositing the spacer layer 720 may be the same as the process chamber for depositing the initiation layer 718. In some embodiments, the spacer layer 720 may be deposited by remote plasma CVD. For example, where the spacer layer 720 is composed of silicon oxycarbide, the plurality of semiconductor device structures 710 may be exposed to silicon-containing precursors such as siloxanes, where the silicon-containing precursors adsorb on the initiation layer 718. The plurality of semiconductor device structures 710 may be exposed to remote plasma, where the remote plasma is generated in a plasma source located upstream of the process chamber. In generating the remote plasma, radicals of source gas such as hydrogen source gas are produced in the remote plasma source. The radicals of the source gas are introduced into the process chamber via a showerhead and flow towards the semiconductor substrate 700, where the radicals react with the adsorbed silicon-containing precursors to form the spacer layer 720. In some embodiments, the radicals are hydrogen radicals in a low energy state (e.g., ground state) in an environment adjacent to the semiconductor substrate 700. The hydrogen radicals may be in an energy state sufficient to selectively break Si—H and Si—Si bonds in the silicon-containing precursors but preserve Si—O and Si—C bonds in the silicon-containing precursors. In some embodiments, the hydrogen radicals may be delivered with inert gas such as argon, helium, neon, krypton, or xenon. In some embodiments, one or more co-reactants may be flowed into the process chamber to react with the silicon-containing precursors to increase or decrease a carbon, oxygen, or nitrogen content of the spacer layer 720. Details regarding remote plasma CVD processes for deposition of silicon-containing films are found in U.S. Pat. No. 10,325,773 to Varadarajan et al., entitled “CONFORMAL DEPOSITION OF SILICON CARBIDE FILMS,” filed Feb. 6, 2015, U.S. patent application Ser. No. 16/044,357 to Weimer et al., entitled “CONFORMAL DEPOSITION OF SILICON CARBIDE FILMS USING HETEROGENEOUS PRECURSOR INTERACTION,” filed Jul. 24, 2018, and U.S. patent application Ser. No. 17/286,407 to Yuan et al., entitled “DOPED OR UNDOPED SILICON CARBIDE DEPOSITION AND REMOTE HYDROGEN PLASMA EXPOSURE FOR GAPFILL,” filed Apr. 16, 2021, each of which is incorporated by reference in its entirety and for all purposes.

One aspect of the present disclosure is an apparatus configured to accomplish the methods described herein. A suitable apparatus includes hardware for accomplishing the process operations and a system controller having instructions for controlling process operations in accordance with the present disclosure. In some embodiments, the apparatus for performing the aforementioned process operations can include a remote plasma source. In some embodiments, the apparatus for performing the aforementioned process operations can include a pedestal for heating the substrate to elevated temperatures.

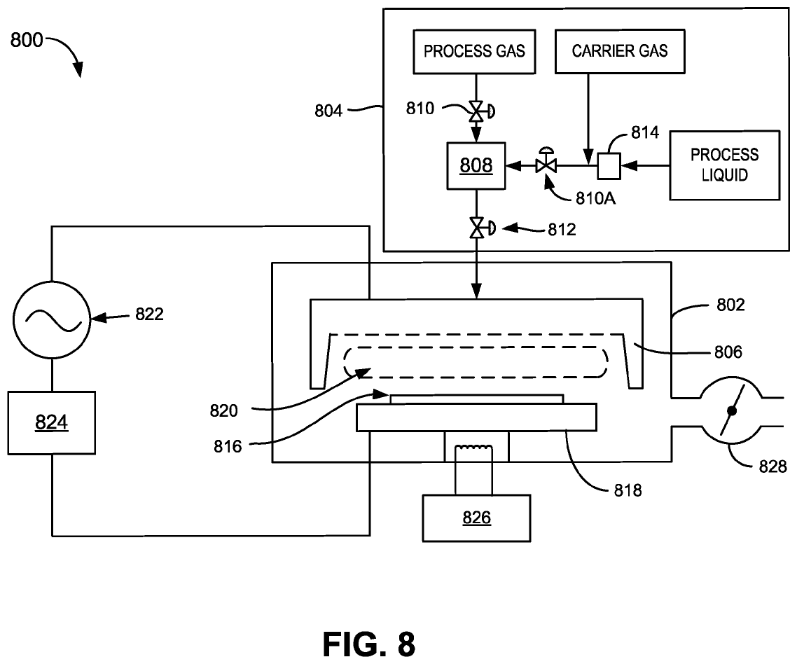

FIG. 8 schematically illustrates a semiconductor processing apparatus for performing deposition according to some embodiments. The semiconductor processing apparatus 800 may be used to deposit a thin layer using ALD or PEALD although it may be adapted for performing other film deposition operations including CVD or PECVD. For simplicity, the semiconductor processing apparatus 800 is depicted as a standalone process station having a reaction chamber 802 for maintaining a low-pressure environment. However, it will be understood that a plurality of the semiconductor processing apparatus 800 may be included in a common process tool environment. Further, it will be understood that, in some embodiments, one or more hardware parameters of the semiconductor processing apparatus 800, including those discussed in detail below, may be adjusted programmatically by one or more computer controllers.

The semiconductor processing apparatus 800 fluidly communicates with reactant delivery system 804 for delivering process gases to a distribution showerhead 806. Reactant delivery system 804 may include a mixing vessel 808 for blending and/or conditioning process gases for delivery to showerhead 806. One or more mixing vessel inlet valves 810 and 810A may control introduction of process gases to mixing vessel 808. Similarly, a showerhead inlet valve 812 may control introduction of process gasses to the showerhead 806.

Some reactants may be stored in liquid form prior to vaporization and subsequent to delivery to the reaction chamber 802. For example, the embodiment of FIG. 8 includes a vaporization point 814 for vaporizing liquid reactant to be supplied to mixing vessel 808. In some embodiments, vaporization point 814 may be a heated vaporizer. The reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 814 may be heat traced. In some examples, mixing vessel 808 may also be heat traced.

In some embodiments, a liquid flow controller upstream of vaporization point 814 may be provided for controlling a mass flow of liquid for vaporization and delivery to the semiconductor processing apparatus 800. For example, the liquid flow controller (LFC) may include a thermal mass flow meter (MFM) located downstream of the LFC.

Showerhead 806 distributes process gases and/or reactants (e.g., film precursors) toward substrate 816. In the embodiment shown in FIG. 8, substrate 816 is located beneath the showerhead 806, and is shown resting on a pedestal 818. It will be understood that showerhead 806 may have any suitable shape, and may have any suitable number and arrangement of ports for distributing processes gases to substrate 816.

A chamber space 820 is located beneath showerhead 806. In some embodiments, the pedestal 818 may be raised or lowered to expose the substrate 816 to chamber space 820 and/or to vary a volume of the chamber space 820. Optionally, the pedestal 818 may be lowered and/or raised during portions of the deposition process to modulate process pressure, reactant concentration, etc. within the chamber space 820.

Adjusting a height of pedestal 818 may allow a plasma density to be varied during plasma activation and/or treatment cycles included in the deposition process. At the conclusion of the deposition process phase, pedestal 818 may be lowered during another substrate transfer phase to allow removal of substrate 816 from pedestal 818.

While the example microvolume variations described herein refer to a height-adjustable pedestal, it will be understood that, in some embodiments, a position of showerhead 806 may be adjusted relative to pedestal 818 to vary a volume of the chamber space 820. Further, it will be understood that a vertical position of pedestal 818 and/or showerhead 806 may be varied by any suitable mechanism within the scope of the present disclosure. In some embodiments, pedestal 818 may include a rotational axis for rotating an orientation of substrate 816. It will be understood that, in some embodiments, one or more of these example adjustments may be performed programmatically by one or more suitable computer controllers.

Returning to the embodiment shown in FIG. 8, showerhead 806 and pedestal 818 electrically communicate with RF power supply 822 and matching network 824 for powering a plasma. In some embodiments, the plasma energy may be controlled by controlling one or more of a process station pressure, a gas concentration, an RF source power, an RF source frequency, and a plasma power pulse timing. For example, RF power supply 822 and matching network 824 may be operated at any suitable power to form a plasma having a desired composition of radical species. For example, RF power for an inductively-coupled plasma for a 300-mm wafer can be between about 300 Watts and about 10 Kilowatts, or between about 1 Kilowatt and about 6 Kilowatts. Likewise, RF power supply 822 may provide RF power of any suitable frequency. In some embodiments, RF power supply 822 may be configured to control high-and low-frequency RF power sources independently of one another. Example low-frequency RF frequencies may include, but are not limited to, frequencies between 50 kHz and 600 kHz. Example high-frequency RF frequencies may include, but are not limited to, frequencies between 1.8 MHz and 2.45 GHZ. It will be understood that any suitable parameters may be modulated discretely or continuously to provide plasma energy for the surface reactions. In one non-limiting example, the plasma power may be intermittently pulsed to reduce ion bombardment with the substrate surface relative to continuously powered plasma.

In some embodiments, the semiconductor processing apparatus 800 is controlled with appropriate hardware and/or appropriate machine-readable instructions in a system controller which may provide control instructions via a sequence of input/output control (IOC) sequencing instructions. In one example, the instructions for setting plasma conditions for a plasma process phase may be included in a corresponding plasma activation recipe phase of a deposition process recipe. In some cases, process recipe phases may be sequentially arranged, so that all instructions for a deposition process phase are executed concurrently with that process phase. In some embodiments, instructions for setting one or more plasma parameters may be included in a recipe phase preceding a plasma process phase. For example, a first recipe phase may include instructions for setting a flow rate of an inert and/or a reactant gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be understood that these recipe phases may be further subdivided and/or iterated in any suitable way within the scope of the present disclosure.

In some embodiments, pedestal 818 may be temperature controlled via temperature control elements 826. Further, in some embodiments, pressure control for the semiconductor process apparatus 800 may be provided by butterfly valve 828. As shown in the embodiment of FIG. 8, butterfly valve 828 throttles a vacuum provided by a downstream vacuum pump (not shown). However, in some embodiments, pressure control of the semiconductor process apparatus 800 may also be adjusted by varying a flow rate of one or more gases introduced to the semiconductor process apparatus 800.

FIG. 9 illustrates a schematic diagram of an example plasma processing apparatus with a remote plasma source according to some embodiments. It will be understood that the plasma processing apparatus in FIG. 9 may be used to deposit an amorphous silicon/boron layer and spacer layer according to some embodiments, and optionally treat the amorphous silicon/boron layer to form a silicon-based or boron-based layer according to some embodiments. In some embodiments, an initiation layer (e.g., amorphous silicon, silicon-based layer, amorphous boron, or boron-based layer) and spacer layer may be deposited without exposure to ambient atmosphere.

The plasma processing apparatus 900 includes a reaction chamber 910 with a showerhead 920. Inside the reaction chamber 910, a substrate 930 rests on a stage or pedestal 935. In some embodiments, the pedestal 935 can be fitted with a heating/cooling element. A controller 940 may be connected to the components of the plasma processing apparatus 900 to control the operation of the plasma processing apparatus 900. For example, the controller 940 may contain instructions for controlling process conditions for the operations of the plasma processing apparatus 900, such as the temperature process conditions and/or the pressure process conditions. In some embodiments, the controller 940 may contain instructions for controlling the flow rates of precursor gas, reactant gas, source gas, and/or carrier gas. The controller 940 may contain instructions for changing the flow rate of the reactant gas, source gas, and/or carrier gas over time. The controller 940 may contain instructions for controlling the chamber pressure, substrate temperature, RF power, exposure time, gas composition, and relative concentrations of the gas composition. A more detailed description of the controller 940 is provided below.

During operation, gases or gas mixtures are introduced into the reaction chamber 910 via one or more gas inlets coupled to the reaction chamber 910. In some embodiments, two or more gas inlets are coupled to the reaction chamber 910. A first gas inlet 955 can be coupled to the reaction chamber 910 and connected to a vessel 950, and a second gas inlet 965 can be coupled to the reaction chamber 910 and connected to a remote plasma source 960. In some embodiments, the second gas inlet 965 may provide carrier gas to the reaction chamber 910. In embodiments including remote plasma source, the delivery lines for the precursors and the radical species generated in the remote plasma source are separated. Hence, the precursors and the radical species do not substantially interact before reaching the substrate 930. It will be understood that in some embodiments the gas lines may be reversed so that the vessel 950 may provide precursor gas flow through the second gas inlet 965 and the remote plasma source 960 may provide ions and radicals through the first gas inlet 955.

One or more radical species may be generated in the remote plasma source 960 and configured to enter the reaction chamber 910 via the second gas inlet 965. Any type of plasma source may be used in remote plasma source 960 to create the radical species. This includes, but is not limited to, an inductively coupled plasma (ICP) source, a capacitively coupled plasma (CCP) source, a microwave plasma source, a DC plasma source, and a laser-created plasma source. An example of a capacitively coupled plasma can be a radio frequency (RF) plasma. A high-frequency plasma can be configured to operate at 13.56 MHz or higher. An example of such a remote plasma source 960 can be the GAMMA®, manufactured by Lam Research Corporation of Fremont, California. Another example of such a remote plasma source 960 can be the Astron®, manufactured by MKS Instruments of Wilmington, Massachusetts, which can be operated at 440 kHz and can be provided as a subunit bolted onto a larger apparatus for processing one or more substrates in parallel. In some embodiments, a microwave plasma can be used as the remote plasma source 960, such as the Astex®, also manufactured by MKS Instruments. A microwave plasma can be configured to operate at a frequency of 2.45 GHZ. Gas species provided to the remote plasma source 960 may include hydrogen, nitrogen, oxygen, carbon, or other gases as mentioned elsewhere herein. In certain embodiments, hydrogen is provided in a carrier such helium. As an example, hydrogen gas may be provided in a helium carrier at a concentration of about 1-50% volume hydrogen.

The precursors can be provided in vessel 950 and can be supplied to the showerhead 920 via the first gas inlet 955. The showerhead 920 distributes the precursors into the reaction chamber 910 toward the substrate 930. The substrate 930 can be located beneath the showerhead 920. It will be understood that the showerhead 920 can have any suitable shape, and may have any number and arrangement of ports for distributing gases to the substrate 930. The precursors can be supplied to the showerhead 920 and ultimately to the substrate 930 at a controlled flow rate.

The one or more radical species formed in the remote plasma source 960 can be carried in the gas phase toward the substrate 930. The one or more radical species can flow through a second gas inlet 965 into the reaction chamber 910. It will be understood that the second gas inlet 965 need not be transverse to the surface of the substrate 930 as illustrated in FIG. 9. In certain embodiments, the second gas inlet 965 can be directly above the substrate 930 or in other locations. The distance between the remote plasma source 960 and the reaction chamber 910 can be configured to provide mild reactive conditions such that the ionized species generated in the remote plasma source 960 are substantially neutralized, but at least some radical species in low energy states or ground states remain in the environment adjacent to the substrate 930. Such low energy state radical species are not recombined to form stable compounds. The distance between the remote plasma source 960 and the reaction chamber 910 can be a function of the aggressiveness of the plasma (e.g., determined in part by the source RF power level), the density of gas in the plasma (e.g., if there's a high concentration of hydrogen atoms, a significant fraction of them may recombine to form H₂ before reaching the reaction chamber 910), and other factors. In some embodiments, the distance between the remote plasma source 960 and the reaction chamber 910 can be between about 1 cm and 30 cm, such as about 5 cm or about 15 cm.

In some embodiments, a co-reactant, which is not the primary silicon-containing precursor or a hydrogen radical, is introduced during the deposition reaction and/or the remote plasma etch. In some embodiments, the plasma processing apparatus 900 is configured to introduce the co-reactant through the second gas inlet 965, in which case the co-reactant is at least partially converted to plasma. In some embodiments, the plasma processing apparatus 900 is configured to introduce the co-reactant through the showerhead 920 via the first gas inlet 955. Examples of the co-reactant include oxygen, nitrogen, ammonia, carbon dioxide, carbon monoxide, and the like. The flow rate of the co-reactant can vary over time to produce a composition gradient in a graded film.

In some embodiments, a gas plasma flow may be generated from the remote plasma source 960. A gas plasma flow from the remote plasma source 960 may include ions, radicals, charged neutrals, and other reactive species of the reactant gas. For instance, the reactive species may include radical species of hydrogen, nitrogen, oxygen, carbon, or amine that may be supplied to the surface of the substrate 930 for a remote plasma deposition and/or conversion.

FIG. 10 illustrates a schematic diagram of an example plasma processing apparatus with a remote plasma source according to some embodiments. It will be understood that the reaction chamber in FIG. 10 may be used to deposit a silicon-containing layer, and/or treat the silicon-containing layer formed in the reaction chamber according to some embodiments. It will also be understood that the reaction chamber in FIG. 10 may be used to deposit a boron-containing layer, and/or treat the boron-containing layer formed in the reaction chamber according to some embodiments. In some embodiments, a silicon-containing or boron-containing layer may be formed in the reaction chamber, followed by treatment in the same reaction chamber using a remote plasma source without exposing the silicon-containing or boron-containing layer to ambient atmosphere.

The plasma processing apparatus 1000 includes a remote plasma source 1002 separated from a reaction chamber 1004. The remote plasma source 1002 is fluidly coupled with the reaction chamber 1004 via a gas distributor or showerhead 1006. In some embodiments, the showerhead 1006 includes an ion filter for filtering ions to limit ion bombardment damage to a substrate 1012. Radical species and/or ions are generated in the remote plasma source 1002, where the radical species may be supplied to the reaction chamber 1004. Precursors such as silicon-containing precursors or boron-containing precursors are supplied to the reaction chamber 1004 through gas supply line or gas outlet 1008 positioned downstream from the remote plasma source 1002 and from the showerhead 1006.

The substrate 1012 is supported on a substrate support structure or wafer pedestal 1014. The wafer pedestal 1014 may be configured with lift pins or other movable support members to position the substrate 1012 within the deposition/treatment zone 1010. The substrate 1012 may be moved to a position closer or farther from the showerhead 1006. The wafer pedestal 1014 is shown in FIG. 10 as having elevated the substrate 1012 within the deposition/treatment zone 1010.

In some embodiments, the wafer pedestal 1014 includes an electrostatic chuck 1016. The electrostatic chuck 1016 includes one or more electrostatic clamping electrodes 1018 embedded within a body of the electrostatic chuck 1016. In some embodiments, the one or more electrostatic clamping electrodes 1018 may be coplanar or substantially coplanar. The electrostatic clamping electrodes 1018 may be powered by a DC power source or DC chucking voltage (e.g., between about 200 V to about 2000 V) so that the substrate 1012 may be retained on the electrostatic chuck 1016 by electrostatic attractive forces. Power to the electrostatic clamping electrodes 1018 may be provided via first electrical lines 1020. The electrostatic chuck 1016 may further include one or more heating elements 1022 embedded within the body of the electrostatic chuck 1016. The one or more heating elements 1022 may include resistive heaters. In some embodiments, the one or more heating elements 1022 are positioned below the one or more electrostatic clamping electrodes 1018. The one or more heating elements 1022 may be configured to heat the substrate 1012 to a temperature greater than about 450° C., greater than about 500° C., greater than about 550° C., greater than about 600° C., or greater than about 650° C. The one or more heating elements 1022 provide selective temperature control to the substrate 1012. Power to the one or more heating elements 1022 may be provided via second electrical lines 1024.

A coil 1028 is arranged around the remote plasma source 1002, where the remote plasma source 1002 includes an outer wall (e.g., quartz dome). The coil 1028 is electrically coupled to a plasma generator controller 1032, which may be used to form and sustain plasma within a plasma region 1034 via inductively coupled plasma generation. In some embodiments, the plasma generator controller 1032 may include a power supply for supplying power to the coil 1028, where the power can be in a range between about 300 W and about 15 kW per station, or between about 1 kW and about 10 KW per station during plasma generation. In some embodiments, electrodes or antenna for parallel plate or capacitively coupled plasma generation may be used to generate a continuous supply of radicals via plasma excitation rather than inductively coupled plasma generation. Regardless of the mechanism used to ignite and sustain the plasma in the plasma region 1034, radical species may continuously be generated using plasma excitation during a layer formation (e.g., film deposition) and/or remote plasma treatment.

In some embodiments, hydrogen radicals (H^{*}), nitrogen radicals (N^{*}), oxygen radicals (O^{*}), carbon radicals (C^{*}), amine radicals (NH^{*}, NH₂^{*}), or combinations thereof, are generated in the plasma region 1034 under approximately steady-state conditions during steady-state film deposition or a remote plasma treatment as controlled by the plasma generator controller 1032, though transients may occur at the beginning and end of film deposition and/or remote plasma treatment (e.g. remote plasma etch). For example, hydrogen radicals may be generated in the plasma region 1034. In another example, two or more different types of radicals, such as nitrogen-containing radicals and hydrogen radicals, nitrogen-containing radicals and carbon-containing radicals, or nitrogen-containing radicals, carbon-containing radicals, and oxygen-containing radicals, may be generated in the plasma region 1034. Though FIG. 10 shows nitrogen radicals (N^{*}), amine radicals (NH^{*}, NH₂^{*}), and hydrogen radicals (H^{*}), it will be understood that the foregoing radicals are illustrative only and that other radicals may be present additionally or alternatively to the radicals depicted in FIG. 10.

A supply of ions and radicals may be continuously generated within the plasma region 1034 while source gas is being supplied to the remote plasma source 1002. Ions generated in the plasma region 1034 may be filtered out by the ion filter of the showerhead 1006. That way, radicals generated in the plasma region 1034 may be supplied to the substrate 1012 in the reaction chamber 1004 while limiting ion bombardment. Conditions in the remote plasma source 1002, including a composition of the source gas provided to the remote plasma source 1002 and RF power supplied to the coil 1028, may be controlled to optimize generation of desired radical species in the plasma region 1034. In some embodiments, the source gas may include an oxygen-containing reactant such as oxygen, water, ozone, carbon monoxide, carbon dioxide, or nitrogen dioxide, nitrous oxide, carbon-containing reactant such as acetylene, ethylene, or propene, hydrogen-containing reactant such as hydrogen or methane, or nitrogen-containing reactant such as nitrogen, ammonia, diazene, or hydrazine, or mixtures thereof. In some embodiments, the source gas may include hydrogen gas. By way of an example, hydrogen radicals may be generated in the plasma region 1034, where a source gas of hydrogen gas may be provided to the remote plasma source 1002 to provide a gas plasma flow including hydrogen radicals toward the substrate 1012 in the reaction chamber 1004. In one example, nitrogen radicals may be generated along with one or both of amine and hydrogen radicals, where a source gas mixture includes nitrogen gas and one or both of ammonia and hydrogen gas. A concentration of amine radicals or nitrogen radicals may be greater or substantially greater than a concentration of hydrogen radicals for converting an a-Si layer to a doped silicon film such as silicon nitride film. A concentration of nitrogen radicals may be greater or substantially greater than a concentration of hydrogen radicals for depositing silicon nitride film.

In some embodiments, the source gas may be mixed with one or more additional gases. These one or more additional gases may be supplied to the remote plasma source 1002. In some embodiments, the source gas is mixed with one or more additional gases to form a gas mixture, where the one or more additional gases can include a carrier gas. Non-limiting examples of additional gases can include helium, neon, argon, krypton, and xenon. Other examples of additional gases can include hydrogen and ammonia. The one or more additional gases may support or stabilize steady-state plasma conditions within the remote plasma source 1002 or aid in transient plasma ignition or extinction processes. In FIG. 10, a source gas supply 1036 is fluidly coupled with the remote plasma source 1002 for supplying the source gas. In addition, an additional gas supply 338 is fluidly coupled with the remote plasma source 302 for supplying the one or more additional gases. For some embodiments, about 5 sccm to about 10000 sccm, or about 10 sccm to about 200 sccm of source gas may be supplied from a source gas supply 1036. In addition, an additional gas supply 1038 is fluidly coupled with the remote plasma source 1002 for supplying the one or more additional gases. While the embodiment in FIG. 10 depicts the gas mixture of the source gas and the one or more additional gases being introduced through separate gas outlets, it will be understood that the gas mixture may be introduced directly into the remote plasma source 1002. That is, a pre-mixed dilute gas mixture may be supplied to the remote plasma source 1002 through a single gas outlet. When one or more source gases are supplied to the remote plasma source 1002, power is provided to the remote plasma source 1002 that may cause the one or more source gases to dissociate and generate ions and/or radicals in an excited energy state.

Depending on the source gases provided to the remote plasma source 1002, when a plasma source is ignited, one or more gas species may be at least partially converted to ions and/or radicals of the one or more gas species in the remote plasma source 1002. For example, plasma-activated gases 1042, such as ions and/or radicals of nitrogen, hydrogen, carbon, oxygen, amine, or combinations thereof, flow out of the remote plasma source 1002 and into the reaction chamber 1004 via showerhead 1006. Plasma-activated gases 1042 within the showerhead 1006 and within the reaction chamber 1004 are generally not subject to continued plasma excitation therein. The showerhead 1006 may have a plurality of gas ports to diffuse the flow of plasma-activated gases 1042 into the reaction chamber 1004. In some embodiments, the plurality of gas ports may be mutually spaced apart. In some embodiments, the plurality of gas ports may be arranged as an array of regularly spaced apart channels or through-holes extending through a plate separating the remote plasma source 1002 and the reaction chamber 1004. The plurality of gas ports may smoothly disperse and diffuse exiting radicals (including plasma-activated gases 1042) from the remote plasma source 1002 into the deposition zone 1010 of the reaction chamber 1004 while filtering out ions.

Plasma-activated species 1042, such as excited nitrogen, hydrogen, carbon, oxygen, and/or amine radicals, flow out of the remote plasma source 1002 and into the reaction chamber 1004 via showerhead 1006. Plasma-activated species 1042 within the showerhead 1006 and within the reaction chamber 1004 are generally not subject to continued plasma excitation therein. The showerhead 1006 may have a plurality of gas ports to diffuse the flow of plasma-activated species 1042 into the reaction chamber 1004. In some embodiments, the plurality of gas ports may be mutually spaced apart. In some embodiments, the plurality of gas ports may be arranged as an array of regularly spaced apart channels or through-holes extending through a plate separating the remote plasma source 1002 and the reaction chamber 1004. The plurality of gas ports may smoothly disperse and diffuse exiting radicals (including plasma-activated species 1042) from the remote plasma source 1002 into the deposition/treatment zone 1010 of the reaction chamber 1004 while filtering out ions.

With the delivery of the plasma-activated species 1042 to the reaction chamber 1004 from the showerhead 1006, precursor gases 1044 (or other process gases) may be introduced into the reaction chamber 1004. The precursor gases 1044 may include silicon-containing precursors such as silane. Alternatively, the precursor gases 1044 may include boron-containing precursors such as borane. The precursor gases 1044 may be introduced via gas supply lines or gas outlets 1008, where the gas outlets 1008 may be fluidly coupled with a precursor supply source 1040. The gas supply lines 1008 may include mutually spaced apart openings so that the flow of the precursor gases 1044 may be introduced in a direction parallel with the plasma-activated species 1042 flowing from the showerhead 1006. In some embodiments, the gas supply lines 1008 may be located downstream from the showerhead 1006. In some embodiments, the gas supply lines 1008 are part of the showerhead 1006 such as in a dual-plenum showerhead. The dual-plenum showerhead may provide separate outlets/passages for the plasma-activated species 1042 and the precursor gases 1044 to avoid mixing in the showerhead 1006. That way, the precursor gases 1044 may flow into the reaction chamber 1004 via the showerhead 1006 without exposure to plasma in the remote plasma source 1002. The gas supply lines 1008 may be located upstream from the deposition/treatment zone 1010 and the substrate 1012. The deposition/treatment zone 1010 is located within the interior of the reaction chamber 1004 between the gas supply lines 1008 and the substrate 1012.

In film deposition process, a substantial fraction of the precursor gases 1044 may be prevented from mixing with plasma-activated species 1042 in the showerhead 1006 or adjacent to the showerhead 1006. In some embodiments, precursor gases 1044 may be delivered to the substrate 1012 in dose phases of ALD cycles separate from plasma-activated species 1042 delivered to the substrate 1012 during plasma exposure phases of the ALD cycles. Adsorbed precursor gases 1044 may react with radicals of the plasma-activated species 1042 during plasma exposure phases of the ALD cycles to deposit film. In some embodiments, precursor gases 1044 may be delivered to the substrate 1012 in a continuous manner to interact with plasma-activated species 1042 in a deposition/treatment zone 1010 to deposit film by CVD. In some embodiments, the plasma-activated species 1042 may be delivered to the substrate 1012 without delivery of the precursor gases 1044 to treat film.

Gases may be removed from the reaction chamber 1004 via an outlet 1048 that is fluidly coupled to a pump (not shown). Thus, radical species or purge gases may be removed from the reaction chamber 1004.

In some embodiments, a thermal shield (not shown) may be positioned underneath the wafer pedestal 1014. The thermal shield serves as a thermal insulator under the wafer pedestal 1014 to mitigate heat loss via thermal radiation, thereby reducing the amount of power needed to maintain the wafer pedestal 1014 at a particular elevated temperature and also preventing other components within the reaction chamber 1004 from overheating due to excess heat radiated from the wafer pedestal 1014. For example, the thermal shield may be radially offset from the stem 1026 and may have a thin annular-shaped body with a high view factor relative to the underside of the electrostatic chuck 1016. Thus, the annular-shaped thermal shield may reduce radiative heat loss from the wafer pedestal 1014.

The electrostatic chuck 1016 of the wafer pedestal 1014 may chuck/dechuck the substrate 1012 in the plasma processing apparatus 1000 that is configured to operate at high temperatures. Such high temperatures may be greater than about 350° C., greater than about 400° C., greater than about 450° C., greater than about 500° C., or greater than about 550° C.

In some embodiments, a controller 1050 (e.g., system controller) is in operative communication with the plasma processing apparatus 1000. In some embodiments, the controller 1050 includes a processor system 1052 (e.g., microprocessor) configured to execute instructions held in a data system 1054 (e.g., memory). In some embodiments, the controller 1050 may be in communication with the plasma generator controller 1032 to control plasma parameters and/or conditions in the remote plasma source 1002. In some embodiments, the controller 1050 may be in communication with the wafer pedestal 1014 to control pedestal elevation, electrostatic chucking and dechucking, and temperature. In some embodiments, the controller 1050 may control other processing conditions, such as RF power settings, frequency settings, duty cycles, pulse times, pressure within the reaction chamber 1004, pressure within the remote plasma source 1002, gas flow rates from the source gas supply 1036, gas flow rates from the additional gas supply 1038 and other sources, temperature of the wafer pedestal 1014, and temperature of the reaction chamber 1004, among other processing conditions.

The controller 1050 may contain instructions for controlling process conditions for the operation of the plasma processing apparatus 1000. The controller 1050 will typically include one or more memory devices and one or more processors. The processor may include a CPU or computer, analog and/or digital input/output connections, stepper motor controller boards, etc. Instructions for implementing appropriate control operations are executed on the processor. These instructions may be stored on the memory devices associated with the controller 1050 or they may be provided over a network.

In certain embodiments, the controller 1050 controls all or most activities of the plasma processing apparatus 1000 described herein. For example, the controller 1050 may control all or most activities of the plasma processing apparatus 1000 associated with film deposition and/or a remote plasma treatment. The controller 1050 may execute system control software including sets of instructions for controlling the timing, gas composition, gas flow rates, chamber pressure, chamber temperature, RF power levels, substrate position, substrate temperature, and/or other parameters. Other computer programs, scripts, or routines stored on memory devices associated with the controller 1050 may be employed in some embodiments. In a multi-station reactor, the controller 1050 may comprise different or identical instructions for different apparatus stations, thus allowing the apparatus stations to operate either independently or synchronously.

In some embodiments, the controller 1050 may include instructions configured to perform operations such as conformally depositing an amorphous silicon layer on a substrate in the reaction chamber 1004, and exposing the amorphous silicon layer to plasma-activated species 1042 generated in the remote plasma source 1002 to convert the amorphous silicon layer to a doped silicon layer. In some embodiments, the plasma-activated species 1042 includes radicals of nitrogen, oxygen, hydrogen, or carbon.

In some embodiments, the controller 1050 may be configured with instructions to perform operations such as conformally depositing a silicon-based initiation layer on one or more semiconductor device structures of the substrate 1012 in the reaction chamber 1004, where the one or more semiconductor device structures include at least a dielectric capping layer over an electrically conductive layer, and depositing a spacer layer on the silicon-based initiation layer. Specifically, the controller 1050 configured with instructions for depositing the silicon-based initiation layer may be configured with instructions for flowing silane-based precursors to adsorb on the one or more semiconductor device structures of the substrate, and thermally decomposing the silane-based precursors to form an amorphous silicon layer. The amorphous silicon layer may serve as the silicon-based initiation layer. Or, the controller 1050 may be further configured with instructions to expose the substrate 1012 to plasma-activated species 1042 generated from the remote plasma source 1002 to dope the amorphous silicon layer and form a doped silicon layer, where the doped silicon layer serves as the silicon-based initiation layer. In some embodiments, the controller 1050 configured with instructions for depositing the spacer layer is configured with instructions for flowing silicon-containing precursors to adsorb on the silicon-based initiation layer, generating plasma-activated species 1042 including radicals of a source gas in the remote plasma source 1002, and exposing the substrate 1012 to plasma-activated species 1042 to cause the radicals to interact with the adsorbed silicon-containing precursors to deposit the spacer layer.

In some embodiments, the controller 1050 may be configured with instructions to perform operations such as conformally depositing a boron-based initiation layer on one or more semiconductor device structures of the substrate 1012 in the reaction chamber 1004, where the one or more semiconductor device structures include at least a dielectric capping layer over an electrically conductive layer, and depositing a spacer layer on the boron-based initiation layer. Specifically, the controller 1050 configured with instructions for depositing the boron-based initiation layer may be configured with instructions for flowing borane-based precursors to adsorb on the one or more semiconductor device structures of the substrate, and thermally decomposing the borane-based precursors to form an amorphous boron layer. The amorphous boron layer may serve as the boron-based initiation layer. Or, the controller 1050 may be further configured with instructions to expose the substrate 1012 to plasma-activated species 1042 generated from the remote plasma source 1002 to dope the amorphous boron layer and form a doped boron layer, where the doped boron layer serves as the boron-based initiation layer. In some embodiments, the controller 1050 configured with instructions for depositing the spacer layer is configured with instructions for flowing boron-containing precursors to adsorb on the boron-based initiation layer, generating plasma-activated species 1042 including radicals of a source gas in the remote plasma source 1002, and exposing the substrate 1012 to plasma-activated species 1042 to cause the radicals to interact with the adsorbed boron-containing precursors to deposit the spacer layer.

In some embodiments, the plasma processing apparatus 1000 may include a user interface associated with controller 1050. The user interface may include a display screen, graphical software displays of the plasma processing apparatus 1000 and/or process conditions, and user input devices such as pointing devices, keyboards, touch screens, microphones, etc.

The computer program code for controlling the above operations can be written in any conventional computer readable programming language: for example, assembly language, C, C++, Pascal, Fortran, or others. Compiled object code or script is executed by the processor to perform the tasks identified in the program.

Signals for monitoring the process may be provided by analog and/or digital input connections of the controller 1050. The signals for controlling the process are output on the analog and digital output connections of the processing system.

Broadly speaking, the controller 1050 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller 1050 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials (e.g., amorphous silicon), surfaces, circuits, and/or dies of a wafer.

The controller 1050, in some embodiments, may be a part of or coupled to a computer that is integrated with, coupled to the system, otherwise networked to the system, or a combination thereof. For example, the controller 1050 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller 1050 receives instructions in the form of data, which specify parameters for each of the processing steps to be performed during one or more operations. It should be understood that the parameters may be specific to the type of process to be performed and the type of tool that the controller 1050 is configured to interface with or control. Thus, as described above, the controller 1050 may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

In the foregoing description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments are described in conjunction with the specific embodiments, it will be understood that it is not intended to limit the disclosed embodiments.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1-10. (canceled)

11. A method of forming a doped silicon layer, comprising:
forming an amorphous silicon layer on a semiconductor substrate in a reaction chamber; and
exposing the amorphous silicon layer to a gas plasma flow to convert the amorphous silicon layer to the doped silicon layer.

12. The method of claim 11, wherein the gas plasma flow comprises radicals of nitrogen, oxygen, hydrogen, or carbon.

13. The method of claim 11, wherein the gas plasma flow comprises a remote plasma flow.

14. The method of claim 13, further comprising:
generating a remote plasma of a source gas in a remote plasma source; and
introducing the remote plasma as the remote plasma flow through a showerhead into the reaction chamber.

15. The method of claim 14, wherein the source gas comprises nitrogen-containing reactants, hydrogen-containing reactants, hydrocarbons, oxygen or oxide reactants, or combinations thereof.

16. The method of claim 14, wherein the source gas comprises nitrogen (N₂), ammonia (NH₃), diazene (N₂H₂), hydrazine (N₂H₄), acetylene (C₂H₂), ethylene (C₂H₄), propene (C₃H₆), hydrogen (H₂), methane (CH₄), oxygen (O₂), water (H₂O), carbon monoxide (CO), carbon dioxide (CO₂), nitrous oxide (N₂O), nitrogen dioxide (NO₂), or combinations thereof.

17. The method of claim 11, wherein forming the amorphous silicon layer comprises:
flowing a silicon-containing precursor to adsorb on surfaces of the semiconductor substrate; and
thermally decomposing the silicon-containing precursor to form the amorphous silicon layer.

18. The method of claim 17, wherein the silicon-containing precursor comprises silane, disilane, or trisilane.

19. The method of claim 11, where the doped silicon layer comprises silicon oxide, silicon nitride, silicon carbide, silicon oxycarbide, silicon oxynitride, silicon carbonitride, or silicon oxycarbonitride.

20. The method of claim 11, wherein the doped silicon layer comprises a silicon-nitrogen-containing layer, wherein the gas plasma flow comprises one or more of the following gas species: nitrogen (N₂), ammonia (NH₃), diazene (N₂H₂), or hydrazine (N₂H₄).

21. The method of claim 11, wherein the doped silicon layer comprises a silicon-carbon-containing layer, wherein the gas plasma flow comprises one or more of the following gas species: acetylene (C₂H₂), ethylene (C₂H₄), or propene (C₃H₆).

22. The method of claim 11, wherein the gas plasma flow comprises one or more of the following gas species: hydrogen (H₂), or methane (CH₄).

23. The method of claim 11, wherein the doped silicon layer comprises a silicon-oxygen-containing layer, wherein the gas plasma flow comprises one or more of the following gas species: oxygen (O₂), water (H₂O), carbon monoxide (CO), carbon dioxide (CO₂), nitrous oxide (N₂O), or nitrogen dioxide (NO₂).

24. A method of forming a doped silicon layer comprising:
forming a conformal silicon layer on a substrate in a reaction chamber;
generating a remote plasma of a source gas in a remote plasma source, wherein the source gas comprises one or more of the following: nitrogen, oxygen, hydrogen, or carbon; and
exposing the conformal silicon layer to the remote plasma to convert the conformal silicon layer to the doped silicon layer.

25. The method of claim 24, wherein the source gas comprises one or more of the following gas species: hydrogen (H₂), or methane (CH₄).

26. The method of claim 24, wherein the conformal silicon layer comprises an amorphous silicon layer.

27. The method of claim 24, wherein the doped silicon layer comprises silicon oxide, silicon nitride, silicon oxycarbide, silicon oxynitride, silicon carbonitride, or silicon oxycarbonitride.

28. The method of claim 24, wherein the doped silicon layer comprises a silicon-nitrogen-containing layer, wherein the source gas comprises one or more of the following gas species: nitrogen (N₂), ammonia (NH₃), diazene (N₂H₂), or hydrazine (N₂H₄).

29. The method of claim 24, wherein the doped silicon layer comprises a silicon-carbon-containing layer, wherein the source gas comprises one or more of the following gas species: acetylene (C₂H₂), ethylene (C₂H₄), or propene (C₃H₆).

30. The method of claim 24, wherein the doped silicon layer comprises a silicon-oxygen-containing layer, wherein the source gas comprises one or more of the following gas species: oxygen (O₂), water (H₂O) vapor, carbon monoxide (CO), carbon dioxide (CO₂), nitrous oxide (N₂O), or nitrogen dioxide (NO₂).
